(19) United States
(12) Patent Application Publication
(10) Pub. No.: US 2024/0276847 A1
(43) Pub. Date: Aug. 15, 2024

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: YASUSHI ASAOKA, Sakai City, Osaka (JP); JUN SAKUMA, Sakai City, Osaka (JP)

(21) Appl. No.: 18/566,779

(22) PCT Filed: Jul. 13, 2021
(86) PCT No.: PCT/JP2021/026317

§ 371 Date: Dec. 4, 2023

(51) Int. Cl. H10K 59/80; H10K 71/60

(52) U.S. Cl. CPC H10K 59/878; H10K 59/80518; H10K 59/877; H10K 59/879; H10K 59/8793; H10K 71/60

(57) ABSTRACT

A display device includes subpixels including light-emitting elements; reflective portions provided in part of the subpixels and each having a reflective surface inclined with respect to a surface of a substrate; a high refractive index layer provided on a second electrode, and guiding light, to the reflective surface, entering from the second electrode side at an angle equal to or greater than a total reflection critical angle and transmit light entering at an angle less than the total reflection critical angle; a substrate provided to face the surface; and a spacer forming a gap layer having a certain thickness between the substrate and the high refractive index layer provided at least in a region not overlapping the reflective portions in a plan view, and dispose the substrate away from the reflective portions. The refractive index of the high refractive index layer is higher than that of the gap layer.

### TECHNICAL FIELD

The disclosure relates to a display device and a method for manufacturing the display device.

### BACKGROUND ART

In recent years, various display devices provided with light-emitting elements have been developed. In particular, a display device provided with a quantum dot light emitting diode (QLED) or an organic light emitting diode (OLED) has attracted a great deal of attention from the perspectives of achieving lower power consumption, thinner design, higher picture quality, and the like.

In the field of display devices provided with such QLEDs or OLEDs, the development of a light extraction structure to improve front luminance by increasing the amount of light extraction in the front direction of a user has been carried out.

PTL 1 describes a light extraction structure in which a projection formed to cover an end portion of a reflective electrode and an inclined reflective portion provided on the projection are used to provide a gap between a waveguide layer and a sealing member.

### CITATION LIST

### Patent Literature

PTL 1: JP 2004-192977 A

### SUMMARY OF INVENTION

### Technical Problem

However, in the case of the light extraction structure described in PTL 1, since the inclined reflective portion and the sealing member are in direct contact with each other, there is a problem that the breakage of the inclined reflective portion due to friction with the sealing member cannot be prevented.

An aspect of the disclosure has been conceived in consideration of the above-mentioned problem, and an object thereof is to provide a display device capable of increasing the amount of light extraction in the front direction of a user, enhancing the reliability, and suppressing the breakage of a reflective portion and the interference unevenness due to friction with a second substrate, and to provide a method for manufacturing the display device.

### Solution to Problem

In order to solve the above problem, a display device according to the disclosure includes:

a first substrate;

a subpixel including a light-emitting element in which a first electrode configured to reflect visible light, a function layer including a light-emitting layer, and a second electrode configured to transmit visible light are provided on the first substrate in that order from the first substrate side;

a reflective portion provided in part of the subpixel and having a reflective surface inclined with respect to a surface on the light-emitting element side of the first substrate;

a high refractive index layer that is provided on the second electrode, guides light entering from the second electrode side at an angle equal to or greater than a total reflection critical angle, to the reflective surface, and transmits light entering at an angle less than the total reflection critical angle;

a second substrate provided to face the surface on the light-emitting element side of the first substrate; and

a spacer configured to form a gap layer having a certain thickness between the second substrate and the high refractive index layer provided at least in a region not overlapping the reflective portion in a plan view, and dispose the second substrate away from the reflective portion,

wherein a refractive index of the high refractive index layer is higher than a refractive index of the gap layer.

In order to solve the above-mentioned problem, a method for manufacturing a display device according to the disclosure includes:

forming, on a first substrate, a first electrode that reflects visible light;

forming a function layer including a light-emitting layer after the forming a first electrode;

forming a second electrode that transmits visible light after the forming a function layer;

forming a reflective portion having a reflective surface inclined with respect to a surface on a side of the first substrate on which the first electrode is provided;

forming, after the forming a second electrode, a high refractive index layer, on the second electrode, that guides light entering from the second electrode side at an angle equal to or greater than a total reflection critical angle, to the reflective surface, and transmits light entering at an angle less than the total reflection critical angle;

forming a second substrate that faces the surface on the side of the first substrate on which the first electrode is provided after the forming a high refractive index layer; and

forming, after the forming a high refractive index layer and before the forming a second substrate, a spacer that forms a gap layer having a certain thickness between the second substrate and the high refractive index layer provided at least in a region not overlapping the reflective portion in a plan view and having a refractive index lower than a refractive index of the high refractive index layer, and disposes the second substrate away from the reflective portion.

### Advantageous Effects of Invention

An aspect of the disclosure may provide a display device capable of increasing the amount of light extraction in the front direction of a user, enhancing the reliability, and suppressing the breakage of a reflective portion and the interference unevenness due to the friction with the second substrate, and may provide a method for manufacturing the display device.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a substrate including transistors provided in the display device according to the first embodiment.

In FIG. 3. (a) is a cross-sectional view illustrating a schematic configuration of a red subpixel provided in the display device according to the first embodiment, (b) is a cross-sectional view illustrating a schematic configuration of a green subpixel provided in the display device according to the first embodiment, and (c) is a cross-sectional view illustrating a schematic configuration of a blue subpixel provided in the display device according to the first embodiment.

In FIG. 4, (a), (b), (c), (d), (e), (f), and (g) are diagrams illustrating an example of a manufacturing process of the display device according to the first embodiment.

In FIG. 5, (a) is a cross-sectional view illustrating a schematic configuration of a red subpixel provided in a display device according to a second embodiment, (b) is a cross-sectional view illustrating a schematic configuration of a green subpixel provided in the display device according to the second embodiment, and (c) is a cross-sectional view illustrating a schematic configuration of a blue subpixel provided in the display device according to the second embodiment.

In FIG. 6, (a) is an example of a light emission spectrum of each of a red light-emitting layer, a green light-emitting layer, and a blue light-emitting layer provided in the display device according to the second embodiment, and (b) is another example of a light emission spectrum of each of a red light-emitting layer, a green light-emitting layer, and a blue light-emitting layer provided in a display device as a modified example of the second embodiment.

FIG. 7 is a diagram depicting optical transparency characteristics and light absorption characteristics of a high refractive index layer and a layer constituting a spacer that are formed in each of a red subpixel, a green subpixel, and a blue subpixel provided in the display device according to the second embodiment illustrated in FIG. 5.

In FIG. 8, (a) is a plan view illustrating a schematic configuration of the display device according to the second embodiment, and (b) is a plan view illustrating a schematic configuration of a display device as a modified example of the second embodiment.

In FIG. 9, (a) is a cross-sectional view illustrating a schematic configuration of a red subpixel provided in a display device according to a third embodiment, (b) is a cross-sectional view illustrating a schematic configuration of a green subpixel provided in the display device according to the third embodiment, and (c) is a cross-sectional view illustrating a schematic configuration of a blue subpixel provided in the display device according to the third embodiment.

In FIG. 10, (a) is a cross-sectional view illustrating a schematic configuration of a red subpixel provided in a display device according to a fourth embodiment, (b) is a cross-sectional view illustrating a schematic configuration of a green subpixel provided in the display device according to the fourth embodiment, and (c) is a cross-sectional view illustrating a schematic configuration of a blue subpixel provided in the display device according to the fourth embodiment.

In FIG. 11, (a) is a cross-sectional view illustrating a schematic configuration of a red subpixel provided in a display device according to a fifth embodiment, (b) is a cross-sectional view illustrating a schematic configuration of a green subpixel provided in the display device according to the fifth embodiment, and (c) is a cross-sectional view illustrating a schematic configuration of a blue subpixel provided in the display device according to the fifth embodiment

FIG. 12 is a diagram depicting optical transparency characteristics and light absorption characteristics of a high refractive index layer and a layer constituting a spacer that are formed in each of a red subpixel, a green subpixel, and a blue subpixel provided in the display device according to the fifth embodiment illustrated in FIG. 11.

In FIG. 13, (a) is a cross-sectional view illustrating a schematic configuration of a red subpixel provided in a display device according to a sixth embodiment, (b) is a cross-sectional view illustrating a schematic configuration of a green subpixel provided in the display device according to the sixth embodiment, and (c) is a cross-sectional view illustrating a schematic configuration of a blue subpixel provided in the display device according to the sixth embodiment.

FIG. 14 is a diagram depicting optical transparency characteristics and light absorption characteristics of a high refractive index layer and a layer constituting a spacer that are formed in each of a red subpixel, a green subpixel, and a blue subpixel provided in the display device according to the sixth embodiment illustrated in FIG. 13.

In FIG. 15, (a) is a cross-sectional view illustrating a schematic configuration of a red subpixel provided in a display device according to a seventh embodiment, (b) is a cross-sectional view illustrating a schematic configuration of a green subpixel provided in the display device according to the seventh embodiment, and (c) is a cross-sectional view illustrating a schematic configuration of a blue subpixel provided in the display device according to the seventh embodiment.

FIG. 16 is a plan view illustrating a schematic configuration of the display device according to the seventh embodiment.

FIG. 17 is a diagram depicting optical transparency characteristics and light absorption characteristics of a high refractive index layer and a layer constituting a spacer that are formed in each of a red subpixel, a green subpixel, and a blue subpixel provided in the display device according to the seventh embodiment illustrated in FIG. 15 and FIG. 16.

In FIG. 18, (a) is a plan view illustrating an example of a shape of a high refractive index layer that is provided for each subpixel in a display device according to an eighth embodiment, (b) is a plan view illustrating an example of a shape of a high refractive index layer that is provided for each subpixel in a display device as a first modified example of the eighth embodiment, and (c) is a plan view illustrating an example of a shape of a high refractive index layer that is provided for each subpixel in a display device as a second modified example of the eighth embodiment.

In FIG. 19, (a) is a plan view illustrating an example of a shape of a high refractive index layer that is provided for each subpixel in a display device as a third modified example of the eighth embodiment, and (b) is a plan view illustrating an example of a shape of a high refractive index layer that is provided for each subpixel of a display device as a fourth modified example of the eighth embodiment

### DESCRIPTION OF EMBODIMENTS

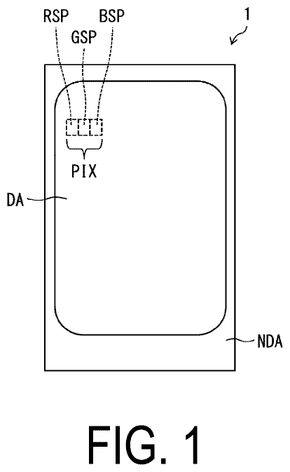

Embodiments of the present invention will be described below with reference to FIG. 1 to FIG. 19. Hereinafter, for convenience of description, configurations having the same functions as those described in a specific embodiment are denoted by the same reference signs, and descriptions thereof will be omitted.

### First Embodiment

FIG. 1 is a plan view illustrating a schematic configuration of a display device 1 according to a first embodiment.

As illustrated in FIG. 1, the display device 1 includes a frame region NDA and a display region DA. A plurality of pixels PIX are provided in the display region DA of the display device 1, and each pixel PIX includes a red subpixel RSP, a green subpixel GSP, and a blue subpixel BSP. In the present embodiment, a case will be described as an example in which one pixel PIX includes the red subpixel RSP, the green subpixel GSP, and the blue subpixel BSP, but no such limitation is intended. For example, one pixel PIX may further include a subpixel of another color in addition to the red subpixel RSP, the green subpixel GSP, and the blue subpixel BSP.

### Substrate 2 Including Transistors TR

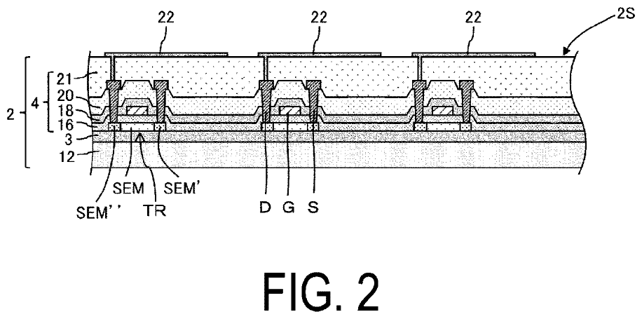

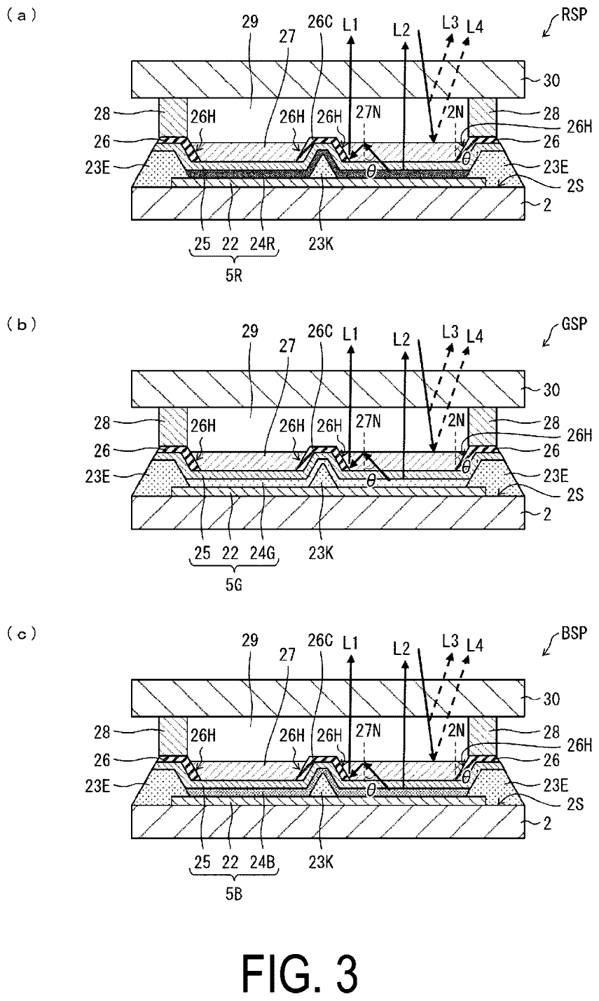

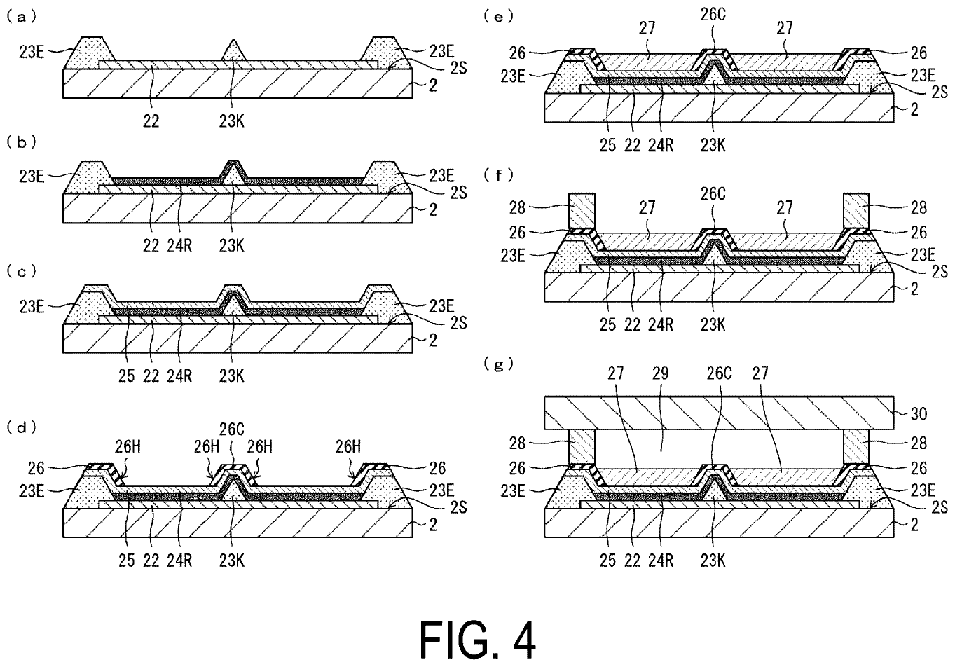

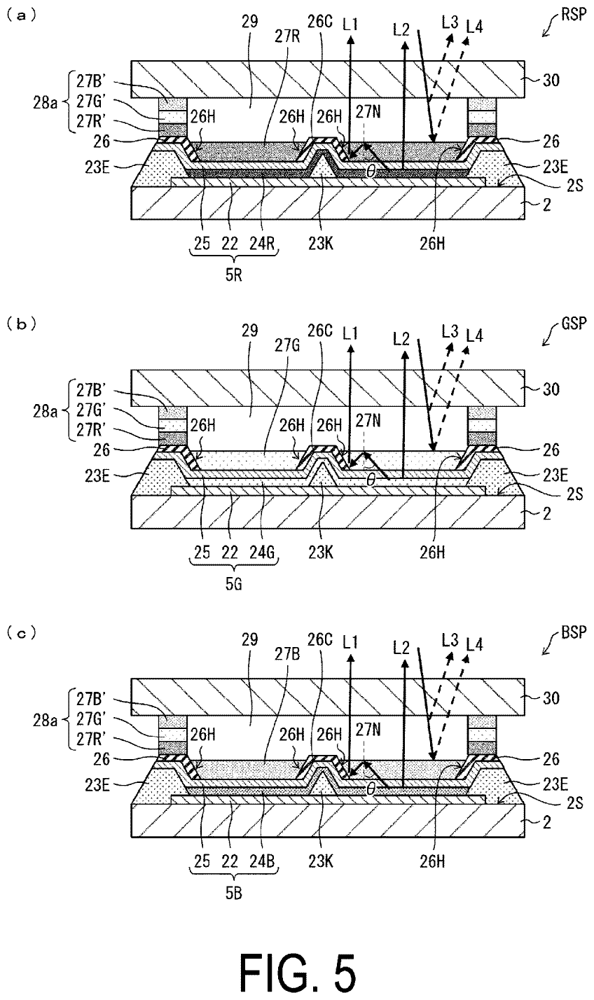

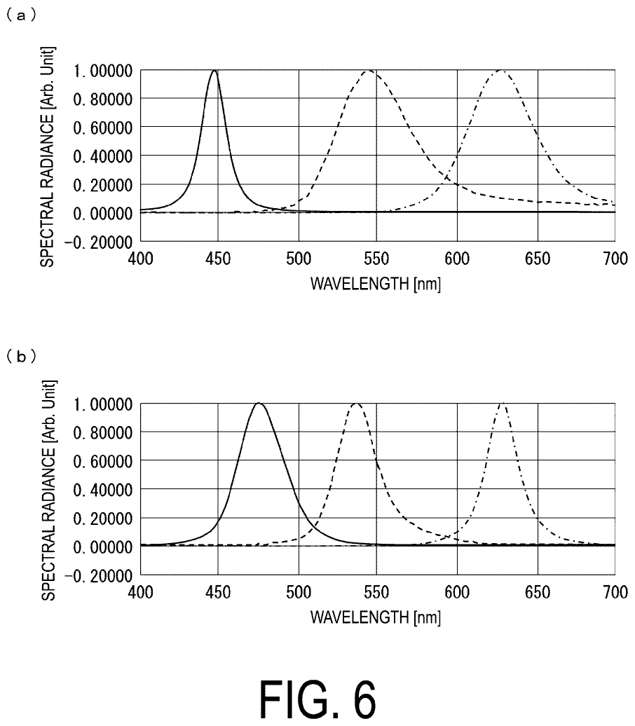

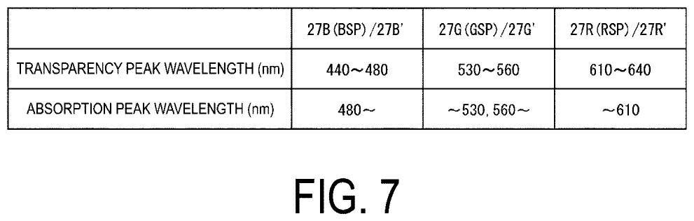

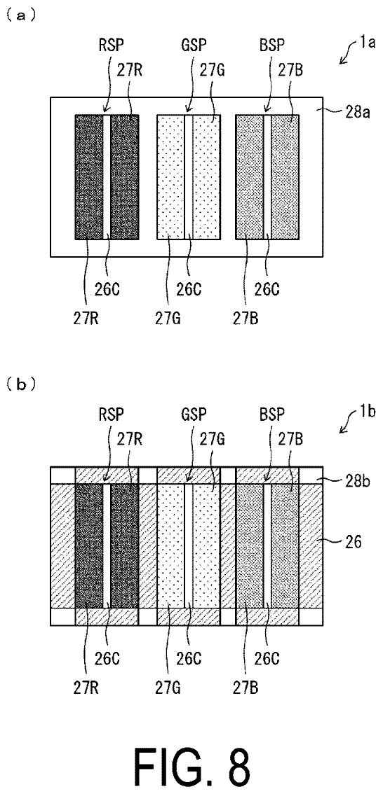

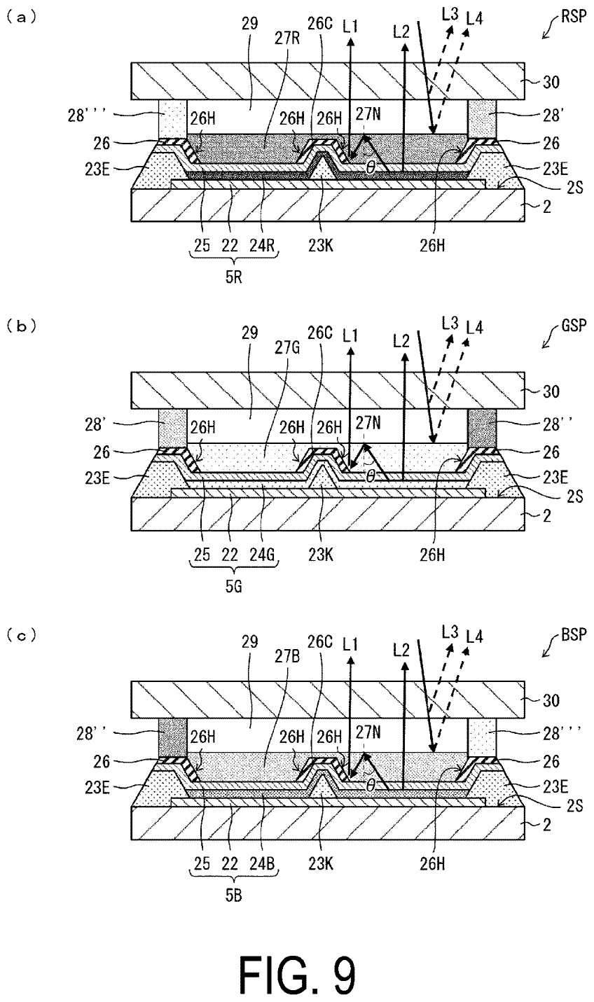

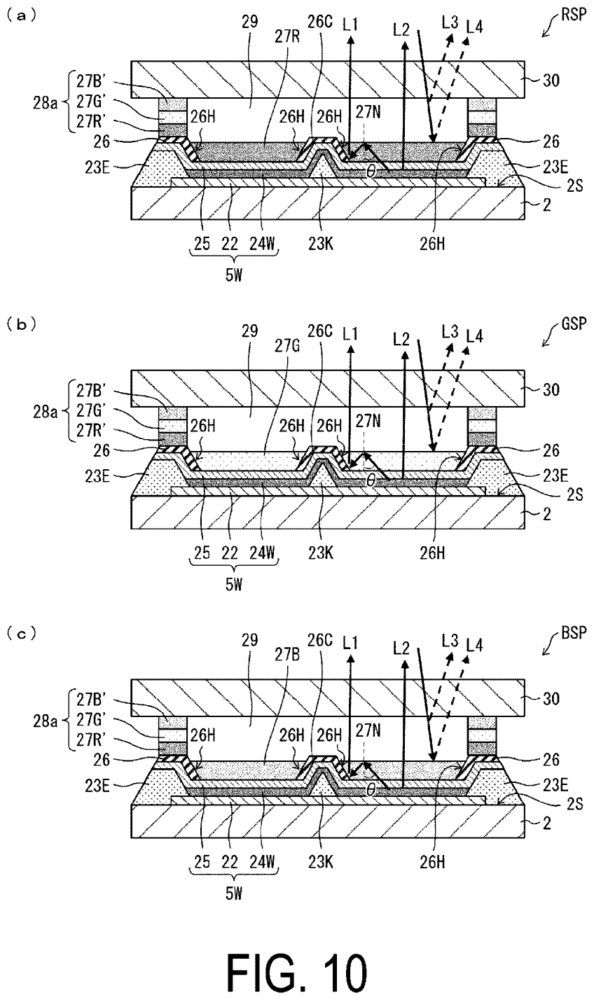

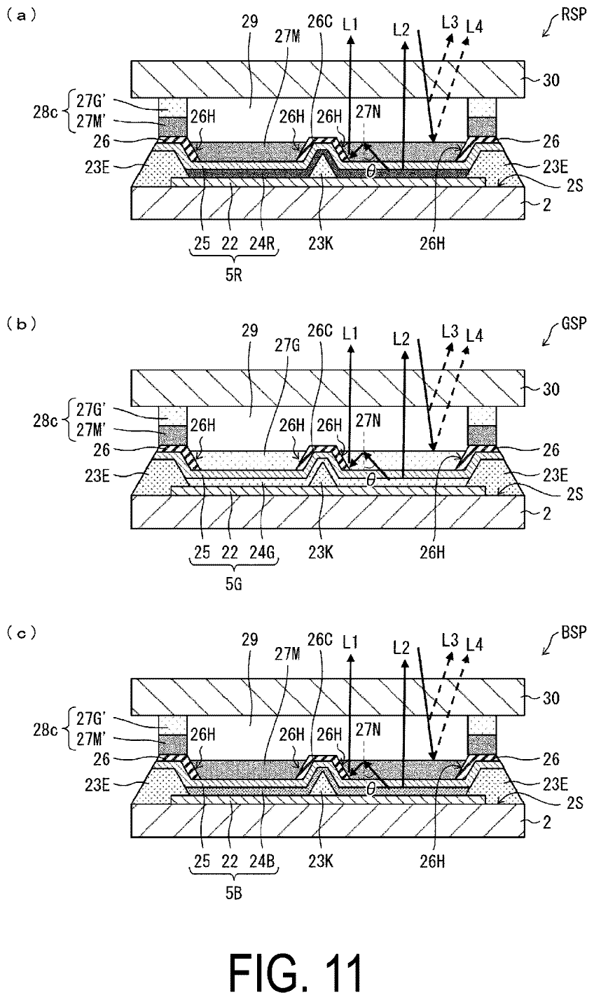

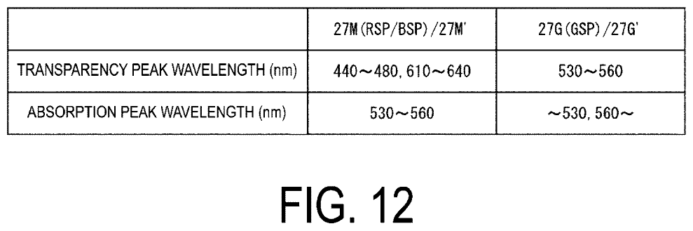

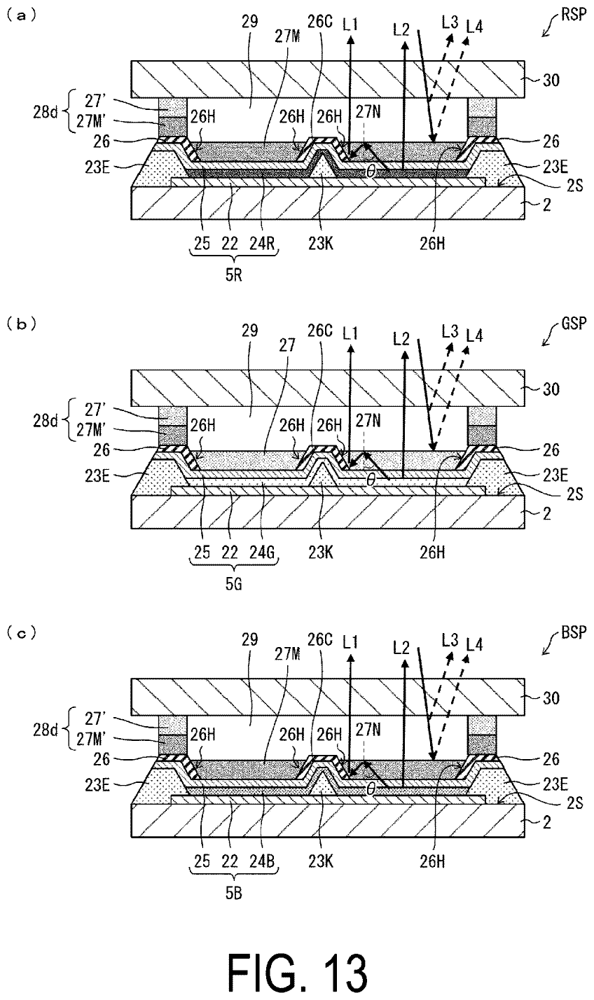

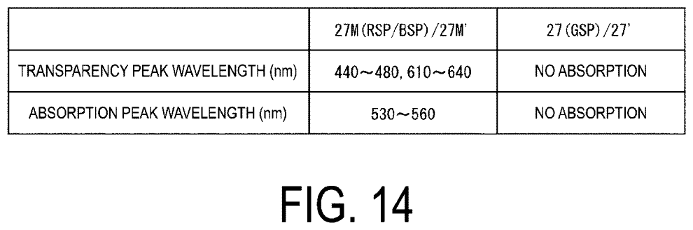

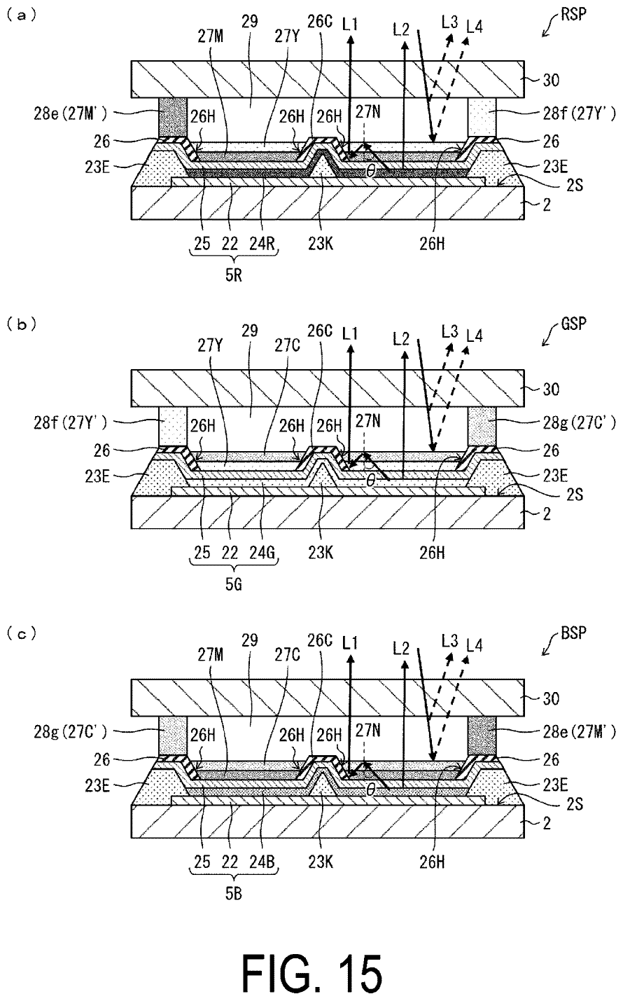

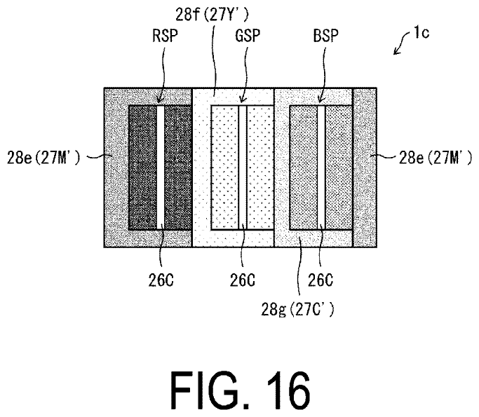

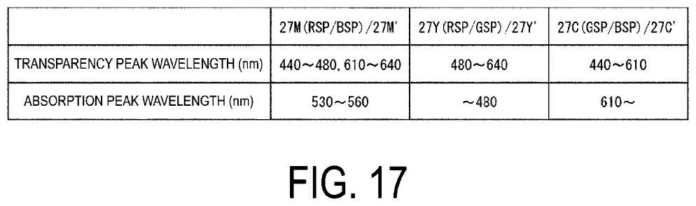

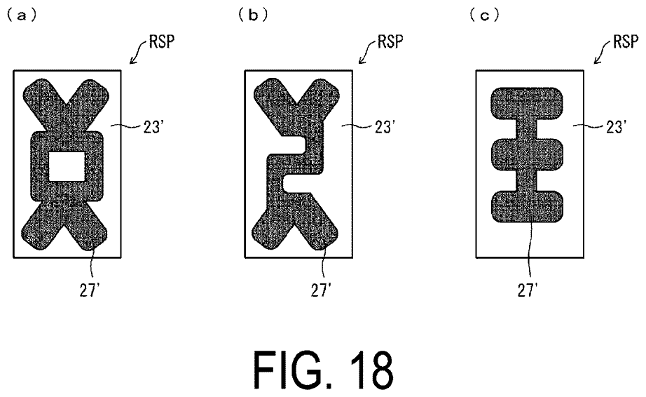

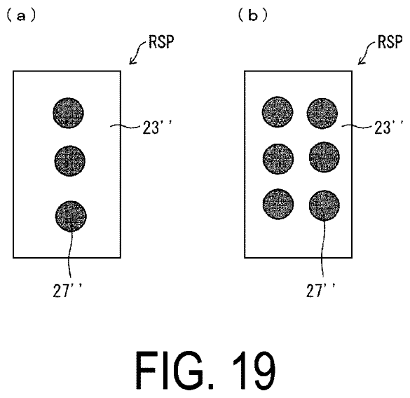

FIG. 2 is a cross-sectional view illustrating a schematic configuration of a substrate 2 including transistors TR provided in the display device 1 according to the first embodiment.

As illustrated in FIG. 2, in the substrate (first substrate) 2 including the transistors TR provided in the display device 1, a barrier layer 3 and a thin film transistor layer 4 including the transistor TR are provided on a substrate 12 in that order from the substrate 12 side. Then, a first electrode 22 is provided on an upper face of the substrate 2 including the transistors TR, that is, on a surface 2S on the side of a light-emitting element.

The substrate 12 may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the substrate 12. However, no such limitation is intended. In a case where the display device 1 is a non-flexible display device, the glass substrate may be used as the substrate 12.

The barrier layer 3 is a layer that inhibits foreign matter, such as water and oxygen, from penetrating into the transistor TR and the light-emitting element of each color described below. For example, the barrier layer 3 may be constituted of a silicon oxide film, a silicon nitride film or a silicon oxynitride film formed by chemical vapor deposition (CVD), or a layered film thereof.

The transistor TR portion of the thin film transistor layer 4 including the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21. A portion other than the transistor TR portion of the thin film transistor layer 4 including the transistor TR includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O) based semiconductor), for example. In the example of the present embodiment described herein, the transistor TR has a top gate structure. However, no such limitation is intended, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 18, and the inorganic insulating film 20 may be constituted of a silicon oxide film, a silicon nitride film or a silicon oxynitride film formed by chemical vapor deposition (CVD), or a layered film thereof.

The flattening film 21 may be formed of coatable organic materials such as polyimide and acrylic.

As illustrated in FIG. 2, a control circuit including the transistor TR for controlling each of a plurality of the first electrodes 22 is provided in the thin film transistor layer 4 including the transistor TR.

(a) of FIG. 3 is a cross-sectional view illustrating a schematic configuration of a red subpixel RSP provided in the display device 1 according to the first embodiment, (b) of FIG. 3 is a cross-sectional view illustrating a schematic configuration of a green subpixel GSP provided in the display device 1 according to the first embodiment, and (c) of FIG. 3 is a cross-sectional view illustrating a schematic configuration of a blue subpixel BSP provided in the display device 1 according to the first embodiment.

Red Light-Emitting Element 5R, Green Light-Emitting Element 5G, Blue Light-Emitting Element 5B

The red subpixel RSP provided in the display region DA of the display device 1 includes a red light-emitting element 5R (first light-emitting element) as illustrated in (a) of FIG. 3, the green subpixel GSP provided in the display region DA of the display device 1 includes a green light-emitting element 5G (second light-emitting element) as illustrated in (b) of FIG. 3, and the blue subpixel BSP provided in the display region DA of the display device 1 includes a blue light-emitting element 5B (third light-emitting element) as illustrated in (c) of FIG. 3.

The red light-emitting element 5R included in the red subpixel RSP illustrated in (a) of FIG. 3 includes the first electrode 22, a function layer 24R including a red light-emitting layer, and a second electrode 25 in that order from the substrate 2 side including the transistors TR. The green light-emitting element 5G included in the green subpixel GSP illustrated in (b) of FIG. 3 includes the first electrode 22, a function layer 24G including a green light-emitting layer, and the second electrode 25 in that order from the substrate 2 side including the transistors TR. The blue light-emitting element 5B included in the blue subpixel BSP illustrated in (c) of FIG. 3 includes the first electrode 22, a function layer 24B including a blue light-emitting layer, and the second electrode 25 in that order from the substrate 2 side including the transistors TR. The first electrode 22 reflects visible light, and the second electrode 25 transmits visible light.

The red light-emitting element 5R, the green light-emitting element 5G, and the blue light-emitting element 5B illustrated in (a) of FIG. 3, (b) of FIG. 3, and (c) of FIG. 3, respectively, may have a regular layered structure in which the first electrode 22 is an anode and the second electrode 25 is a cathode, or may have an inverted layered structure in which the first electrode 22 is a cathode and the second electrode 25 is an anode. In the case of the regular layered structure, it is sufficient that the first electrode 22 serving as the anode is formed of an electrode material that reflects visible light, and the second electrode 25 serving as the cathode is formed of an electrode material that transmits visible light. In the case of the inverted layered structure, it is sufficient that the first electrode 22 serving as the cathode is formed of an electrode material that reflects visible light, and the second electrode 25 serving as the anode is formed of an electrode material that transmits visible light.

The electrode material that reflects visible light is not particularly limited as long as the material can reflect visible light and has electrical conductivity. Examples thereof include metal materials such as Al, Mg, Li and Ag, alloys of these metal materials, a layered body of the above metal materials and transparent metal oxides (for example, indium tin oxide, indium zinc oxide, and indium gallium zinc oxide), and a layered body of the alloys and the transparent metal oxides.

On the other hand, the electrode material that transmits visible light is not particularly limited as long as the material can transmit visible light and has electrical conductivity. Examples thereof include a transparent metal oxide (for example, indium tin oxide, indium zinc oxide, or indium gallium zinc oxide), a thin film made of a metal material such as Al, Mg, Li or Ag, and a conductive nano material such as a silver nanowire or a carbon nanotube.

A typical electrode forming method may be used as a film formation method of the first electrode 22 and the second electrode 25, and examples thereof include physical vapor deposition (PVD) such as vacuum vapor deposition, sputtering, electron beam (EB) vapor deposition and ion plating, chemical vapor deposition (CVD), and application of dispersion of a conductive nano material. Further, the method of patterning the first electrode 22 and the second electrode 25 is not particularly limited as long as the method is capable of precisely forming a desired pattern, and specific examples thereof include a photolithography method and an ink-jet method.

### Edge Cover Layer 23E and Structural Body 23K

As illustrated in (a) of FIG. 3, (b) of FIG. 3, and (c) of FIG. 3, the display device 1 further includes an edge cover layer 23E covering an end portion of the first electrode 22 provided in each of the red subpixel RSP, the green subpixel GSP, and the blue subpixel BSP. After applying a photosensitive organic material such as polyimide or acrylic, the edge cover layer 23E can be formed through patterning by a photolithography method, for example.

Since the display device 1 includes a spacer 28 described below in addition to the edge cover layer 23E, the edge cover layer 23E is allowed to be formed relatively low with a level of height (thickness) sufficient to cover the end portion of the first electrode 22. Accordingly, since the height of the edge cover layer 23E is relatively low, the edge cover layer 23E is not formed wider than necessary by the photolithography method, and thus the light-emitting region is not thinned as the width of the edge cover layer 23E formed between the adjacent first electrodes 22 increases.

In a case where a reflective surface 26H of a reflective portion 26 described below is formed to be high without making use of the height of the edge cover layer 23E, for example, when the height of the edge cover layer 23E is formed to be low (thin), it is preferable to form the reflective portion 26 itself to be thick in order to maintain the height of the reflective surface 26H of the reflective portion 26 to be high. This is because when the height of the reflective surface 26H of the reflective portion 26 is low, the thickness of a high refractive index layer 27 described below becomes thin, and the number of times of reflection of the light guided in the high refractive index layer 27 until the light reaches the reflective surface 26H of the reflective portion 26 with the low height increases, thereby decreasing the light emitted from the light-emitting element (5R, 5G, 5B).

In the present embodiment, the edge cover layer 23E is preferably formed in a shape including an inclined face inclined with respect to the surface 2S on the light-emitting element side of the substrate 2 including the transistors TR. By forming the edge cover layer 23E in the shape including the inclined face as described above, it is sufficient to form the reflective surface 26H of the reflective portion 26 described below along the inclined face of the edge cover layer 23E, and thus the reflective surface 26H is relatively easily formed.

In the present embodiment, it is preferable that at least part of the reflective portion 26 including the reflective surface 26H overlap the edge cover layer 23E in a plan view (when viewed from the side of a second substrate 30). With such a configuration, it is possible to suppress a situation in which the light-emitting region is narrowed in the display device 1.

In the present embodiment, as illustrated in (a) of FIG. 3. (b) of FIG. 3, and (c) of FIG. 3, a case where the display device 1 includes the edge cover layer 23E and a structural body 23K will be described as an example, but the present invention is not limited thereto.

As illustrated in (a) of FIG. 3, (b) of FIG. 3, and (c) of FIG. 3, the structural body 23K overlaps part of any one of the function layer 24R including the red light-emitting layer, the function layer 24G including the green light-emitting layer, and the function layer 24B including the blue light-emitting layer in a plan view, and is provided below a reflective portion 26C including the reflective surface 26H.

In the present embodiment, the structural body 23K is preferably formed in a shape including an inclined face inclined with respect to the surface 2S on the light-emitting element side of the substrate 2 including the transistors TR. By forming the structural body 23K in the shape including the inclined face as described above, it is sufficient to form the reflective surface 26H of the reflective portion 26C described below along the inclined face of the structural body 23K, and thus the reflective surface 26H is relatively easily formed.

In the present embodiment, it is preferable that at least part of the reflective portion 26C including the reflective surface 26H overlap the structural body 23K in a plan view. With such a configuration, it is possible to suppress a situation in which the light-emitting region is narrowed in the display device 1.

As described above, in the case where the display device 1 includes the edge cover layer 23E and the structural body 23K, it is preferable that at least part of the reflective portion 26 including the reflective surface 26H and at least part of the reflective portion 26C including the reflective surface 26H overlap the edge cover layer 23E and the structural body 23K in a plan view With such a configuration, it is possible to suppress a situation in which the light-emitting region is narrowed in the display device 1.

As described above, in the case where each of the edge cover layer 23E and the structural body 23K provided in the display device 1 includes the inclined face inclined with respect to the surface 2S on the light-emitting element side of the substrate 2 including the transistors TR, the reflective surface 26H of each of the reflective portions 26 and 26C is preferably formed along the inclined face. With such a configuration, the reflective surface 26H is relatively easily formed.

In the present embodiment, the maximum height of the edge cover layer 23E is preferably higher than the maximum height of the structural body 23K by the thickness of any one of the function layer 24R including the red light-emitting layer, the function layer 24G including the green light-emitting layer, and the function layer 24B including the blue light-emitting layer. As illustrated in (a) of FIG. 3, (b) of FIG. 3, and (c) of FIG. 3, none of the function layer 24R including the red light-emitting layer, the function layer 24G including the green light-emitting layer, and the function layer 24B including the blue light-emitting layer are formed on the edge cover layer 23E, but any one of the function layer 24R including the red light-emitting layer, the function layer 24G including the green light-emitting layer, and the function layer 24B including the blue light-emitting layer is formed on the structural body 23K. Because of this, when the maximum height of the edge cover layer 23E is made higher than the maximum height of the structural body 23K by the thickness of any one of the function layer 24R including the red light-emitting layer, the function layer 24G including the green light-emitting layer, and the function layer 24B including the blue light-emitting layer, the formation position of the reflective surface 26H of the reflective portion 26 may be made substantially equal in height to the formation position of the reflective surface 26H of the reflective portion 26C.

In the present embodiment, the structural body 23K is formed of the same material as that of the edge cover layer 23E. The edge cover layer 23E and the structural body 23K can be formed, after applying a photosensitive organic material such as polyimide or acrylic, through patterning by a photolithography method, for example. As described above, when the maximum height of the edge cover layer 23E is to be formed higher than the maximum height of the structural body 23K, such edge cover layer may be formed by exposing different exposure amounts using a half-tone mask, for example. As described above, when the edge cover layer 23E and the structural body 23K are formed of the same material, the edge cover layer 23E and the structural body 23K may be formed in the same process, and thus the manufacturing manpower may be reduced. The present invention is not limited thereto, and the edge cover layer 23E and the structural body 23K may be formed of different materials.

In the present embodiment, as described above, a case where the display device 1 includes the edge cover layer 23E and the structural body 23K is described as an example, but the present invention is not limited thereto. For example, the display device 1 may include only one of the edge cover layer 23E and the structural body 23K. The display device 1 is allowed not to include both the edge cover layer 23E and the structural body 23K as long as it is possible to form the reflective portions 26 and 26C having the reflective surfaces 26H inclined with respect to the surface 2S on the light-emitting element side of the substrate 2 including the transistors TR. As an example of such a case, the reflective portions 26 and 26C having the reflective surfaces 26H may be formed by forming the shapes of the reflective portions 26 and 26C themselves to be similar to the shape (trapezoidal cross-sectional shape) of the edge cover layer 23E, for example. Furthermore, the display device 1 may include, for example, a structural body having the same shape as the structural body 23K between the adjacent first electrodes 22, instead of the edge cover layer 23E covering the end portion of the first electrode 22.

### Reflective Portions 26 and 26C

As illustrated in (a) of FIG. 3, (b) of FIG. 3, and (c) of FIG. 3, the display device 1 includes, in part of each of the red subpixel RSP, the green subpixel GSP, and the blue subpixel BSP, the reflective portions 26 and 26C having the reflective surfaces 26H inclined with respect to the surface 2S on the light-emitting element side of the substrate 2 including the transistors TR. At least part of the reflective portion 26 having the reflective surface 26H overlaps the edge cover layer 23E in a plan view, and at least part of the reflective portion 26C having the reflective surface 26H overlaps the structural body 23K in the plan view. That is, the reflective portion 26 having the reflective surface 26H is formed to define each of the red subpixel RSP, the green subpixel GSP, and the blue subpixel BSP, and the reflective portion 26C having the reflective surface 26H is formed to pass through a central portion in the right-left direction in the drawing of each of the red subpixel RSP, the green subpixel GSP, and the blue subpixel BSP. However, the present invention is not limited thereto, and the reflective portion 26C having the reflective surface 26H may be formed to pass through a central portion in the up-down direction in the drawing, or may be formed to pass through the central portion in the right-left direction in the drawing and the central portion in the up-down direction in the drawing. Further, a plurality of the reflective portions 26C having the reflective surfaces 26H may be formed.

In the present embodiment, a case will be described as an example in which the entire reflective portions 26 and 26C having the reflective surfaces 26H are formed of a metal material serving as a conductive material that reflects visible light, but the present invention is not limited thereto. For example, only the reflective surface 26H being part of the reflective portions 26 and 26C may include a metal material that reflects visible light.

In the present embodiment, as described above, the entire reflective portions 26 and 26C having the reflective surfaces 26H are formed of a metal material. In other words, the reflective portions 26 and 26C having the reflective surfaces 26H include a conductive material, and are formed on the second electrode 25 to be in contact with the second electrode 25. Thus, since the reflective portions 26 and 26C function as auxiliary electrodes of the second electrode 25, resistance of the second electrode 25 may be reduced.

As in the present embodiment, in the case where the entire reflective portions 26 and 26C having the reflective surfaces 26H are formed of a metal material, that is, in the case where the reflective portions 26 and 26C having the reflective surfaces 26H include a conductive material, the reflective portions 26 and 26C may be formed between the second electrode 25 and any one of the function layer 24R including the red light-emitting layer, the function layer 24G including the green light-emitting layer, and the function layer 24B including the blue light-emitting layer in such a manner, although not illustrated, as to be in contact with both the second electrode 25 and any one of the function layer 24R including the red light-emitting layer, the function layer 24G including the green light-emitting layer, and the function layer 24B including the blue light-emitting layer. In the above-described configuration as well, since the reflective portions 26 and 26C function as auxiliary electrodes of the second electrode 25, resistance of the second electrode 25 may be reduced.

In the present embodiment, since the entire reflective portions 26 and 26C having the reflective surfaces 26H are formed of a metal material serving as a conductive material that reflects visible light, in order to increase the contact areas between the reflective portions 26 and 26C and the second electrode 25, and enhance the function of each of the reflective portions 26 and 26C as an auxiliary electrode of the second electrode 25, the reflective portions 26 and 26C are each formed in such a manner as to include a flat portion that is formed to face the surface 2S on the light-emitting element side of the substrate 2 including the transistors TR together with the reflective surface 26H inclined with respect to the surface 2S on the light-emitting element side of the substrate 2 including the transistors TR, as illustrated in (a) of FIG. 3, (b) of FIG. 3, and (c) of FIG. 3. As illustrated in (a) of FIG. 3, (b) of FIG. 3, and (c) of FIG. 3, in the case where the reflective portions 26 and 26C are formed in a shape in which the reflective surface 26H and the flat portion of the reflective portions 26 and 26C are connected to each other, the formation widths of the reflective portions 26 and 26C become wide, so that high-resolution patterning is not required in the patterning process of the reflective portions 26 and 26C. Thus, the yield may be improved and the productivity of the display device 1 may be improved.

The reflective portions 26 and 26C may contain a light scattering agent. The reflective portions 26 and 26C may not be formed of a metal material serving as a conductive material that reflects visible light, but may be formed of, for example, a resin containing a light scattering agent in order that the reflective portions 26 and 26C have only a reflecting function. In the case where the reflective portions 26 and 26C are formed of a resin containing a light scattering agent, since the reflective portions 26 and 26C do not have electrical conductivity, the reflective portions 26 and 26C may be formed of only the reflective surfaces 26H, without including the flat portion.

In the present embodiment, for example, Ag is used as a metal material serving as a conductive material that forms the reflective portions 26 and 26C and reflects visible light, but the present invention is not limited thereto. Al may be used, a layered film of Al and Ag may be used, or a metal material such as an alloy containing Al or Ag may be used As the light scattering agent, for example, titanium oxide particles may be used

In the present embodiment, as illustrated in (a) of FIG. 3, (b) of FIG. 3, and (c) of FIG. 3, a case will be described as an example in which the reflective portions 26 and 26C having the reflective surfaces 26H are provided above the function layer 24R including the red light-emitting layer, the function layer 24G including the green light-emitting layer, and the function layer 24B including the blue light-emitting layer, but the present invention is not limited thereto as long as the light guided from the high refractive index layer 27 described below can be reflected.

In the present embodiment, as illustrated in (a) of FIG. 3, (b) of FIG. 3, and (c) of FIG. 3, a case will be described as an example in which the reflective surfaces 26H of the reflective portions 26 and 26C are each provided on a side surface of the high refractive index layer 27 described below, but the present invention is not limited thereto as long as the light guided from the high refractive index layer 27 can be reflected.

As illustrated in (a) of FIG. 3, (b) of FIG. 3, and (c) of FIG. 3, the reflective surface 26H inclined with respect to the surface 2S on the light-emitting element side of the substrate 2 including the transistors TR is preferably provided in such a manner that an angle θ′ formed between the reflective surface 26H and a perpendicular line 2N of the surface 2S on the light-emitting element side of the substrate 2 including the transistors TR is in a range from 65° to 80°, but the present invention is not limited thereto.

### High Refractive Index Layer 27

As illustrated in (a) of FIG. 3, (b) of FIG. 3, and (c) of FIG. 3, the high refractive index layer 27 is provided on the second electrode 25. In the present embodiment, a case will be described as an example in which the high refractive index layer 27 covers part of the reflective surfaces 26H of the reflective portions 26 and 26C and the second electrodes 25, but the present invention is not limited thereto. As in a third embodiment to be described later, the high refractive index layer 27 may be formed to cover the second electrode 25 and the entire reflective portions 26 and 26C having the reflective surfaces 26H.

The high refractive index layer 27 may be formed of a photosensitive high refractive index resin. Examples of the high refractive index resin include a nanocomposite (a combination of an organic polymer matrix and inorganic nanoparticles having a high refractive index) having a high refractive index such as acrylate to which zirconia, hafnium or the like is added, and a polymer material having a high refractive index such as polyimide or polyester having a refractive index of 1.6.

In the high refractive index layer 27 formed of a high refractive index resin, the total reflection critical angle is determined by the refractive index of the high refractive index resin. The upper face of the high refractive index layer 27 (the surface opposing a surface on the second electrode 25 side of the high refractive index layer 27) is in contact with a gap layer 29 described below having a refractive index lower than the refractive index of the high refractive index layer 27. When an angle θ formed between a straight line 27N in the thickness direction (the up-down direction in the drawing) of the high refractive index layer 27 and the light entering the high refractive index layer 27 from the second electrode 25 side (the light after being refracted in the high refractive index layer 27) is equal to or larger than the total reflection critical angle, the high refractive index layer 27 may guide, to the reflective surface 26H, the light entering from the second electrode 25 side and traveling obliquely at an angle equal to or larger than the total reflection critical angle, and may make the light emitted as light L1 in the front direction. On the other hand, when the angle θ formed between the straight line 27N in the thickness direction of the high refractive index layer 27 and the light entering the high refractive index layer 27 from the second electrode 25 side (the light after being refracted in the high refractive index layer 27) is less than the total reflection critical angle, the high refractive index layer 27 transmits light L2 entering from the second electrode 25 side and traveling at an angle less than the total reflection critical angle as it is. Thus, the display device 1 may increase the amount of light extraction in the front direction of the user.

### Spacer 28

As illustrated in (a) of FIG. 3, (b) of FIG. 3, and (c) of FIG. 3, each of the red subpixel RSP, the green subpixel GSP, and the blue subpixel BSP of the display device 1 is provided with the spacer 28, which forms the gap layer 29 having a certain thickness between the second substrate 30 and the high refractive index layer 27 provided at least in a region overlapping none of the reflective portions 26 and 26C in a plan view and disposes the second substrate 30 away from the reflective portions 26 and 26C.

In the present embodiment, the spacer 28 is formed on the edge cover layer 23E covering the end portion of the first electrode 22 along the shape of the edge cover layer 23E (see a spacer 28a in (a) of FIG. 9). Without being limited thereto, the spacer 28 may be formed in a dot shape on the edge cover layer 23E covering the end portion of the first electrode 22 (see a spacer 28b in (b) of FIG. 9).

In the present embodiment, as illustrated in (a) of FIG. 3, (b) of FIG. 3, and (c) of FIG. 3, the high refractive index layers 27 formed of photosensitive high refractive index resins made of the same material are respectively formed on the second electrode 25 of the red subpixel RSP, the second electrode 25 of the green subpixel GSP, and the second electrode 25 of the blue subpixel BSP.

In the present embodiment, the spacer 28 and the high refractive index layer 27 are formed of photosensitive high refractive index resins made of the same material, and the photosensitive high refractive index resin that can be patterned by exposure and development is used as the high refractive index resin discussed above, but the present invention is not limited thereto For example, the spacer 28 may be formed of a material different from that of the high refractive index layer 27 as long as the gap layer 29 having a certain thickness can be formed between the second substrate 30 and the high refractive index layer 27 provided at least in a region overlapping none of the reflective portions 26 and 26C in a plan view, and the second substrate 30 can be disposed away from the reflective portions 26 and 26C.

When the spacer 28 and the high refractive index layer 27 are to be formed of photosensitive high refractive index resins made of the same material as in the present embodiment, first, the photosensitive high refractive index resin is applied on the entire surface in accordance with the height of the spacer 28. Thereafter, the high refractive index layer 27 and the spacer 28 can be formed at the same time by performing exposure using, for example, a gray-tone mask (half-tone mask) while setting differences between the exposure amount in a region where the high refractive index layer 27 is formed, the exposure amount in a region where the spacer 28 is formed, and the exposure amount in a region on the flat portion of the reflective portion 26C, and then performing development. The photosensitive high refractive index resin may be positive-working or negative-working. As described above, when the spacer 28 and the high refractive index layer 27 are formed at the same time using the photosensitive high refractive index resins made of the same material, the manufacturing manpower may be reduced and the productivity of the display device 1 may be improved.

### Gap Layer 29

As illustrated in (a) of FIG. 3. (b) of FIG. 3, and (c) of FIG. 3, the gap layer 29 having a certain thickness is formed between the second substrate 30 and the high refractive index layer 27 provided at least in a region overlapping none of the reflective portions 26 and 26C in a plan view. A refractive index n2 of the high refractive index layer 27 is higher than a refractive index n3 of the gap layer 29.

A difference An2n3 between the refractive index n2 of the high refractive index layer 27 and the refractive index n3 of the gap layer 29 is preferably greater than a difference AnIn2 between an average refractive index n1 of any one of the function layer 24R including the red light-emitting layer, the function layer 24G including the green light-emitting layer and the function layer 24B including the blue light-emitting layer, the first electrode 22, and the second electrode 25, and the refractive index n2 of the high refractive index layer 27. With the above configuration, the amount of light extraction in the front direction of the user may be increased.

The average refractive index n1 of any one of the function layer 24R including the red light-emitting layer, the function layer 24G including the green light-emitting layer and the function layer 24B including the blue light-emitting layer, the first electrode 22, and the second electrode 25 is preferably higher than the refractive index n2 of the high refractive index layer 27. That is, it is preferable that the average refractive index n1 be higher than the refractive index n2 of the high refractive index layer 27, and the refractive index n2 of the high refractive index layer 27 be higher than the refractive index n3 of the gap layer 29. With the above configuration, the amount of light extraction in the front direction of the user may be increased.

The aforementioned certain thickness of the gap layer 29 is preferably in a range from 1 μm to 10 μm. When the certain thickness of the gap layer 29 is thinner than 1 μm, since there is only one interference peak in the visible light region, the color change of reflected light becomes large when the viewing angle is changed. On the other hand, when the certain thickness of the gap layer 29 is thicker than 10 μm, the aspect ratio of the spacer 28 becomes high, and the patterning process of the spacer 28 becomes difficult to be carried out.

In the present embodiment, a case will be described as an example in which the gap layer 29 is filled with air serving as a low refractive index medium, but the present invention is not limited to this, and it is sufficient for the gap layer 29 to be filled with a low refractive index medium having a refractive index lower than the refractive index n2 of the high refractive index layer 27. The above-mentioned low refractive index medium may be, for example, a medium containing at least one of a resin having a refractive index lower than the refractive index n2 of the high refractive index layer 27, a hollow bead having a refractive index lower than the refractive index n2 of the high refractive index layer 27, and the air.

### Second Substrate 30

As illustrated in (a) of FIG. 3, (b) of FIG. 3, and (c) of FIG. 3, the second substrate 30 is provided to face the surface 2S on the light-emitting element side of the substrate 2 including the transistors TR. The second substrate 30 is preferably a glass substrate or a non-flexible resin substrate, but is not particularly limited thereto as long as the gap layer 29 having a certain thickness is formed between the second substrate 30 and the high refractive index layer 27 provided at least in a region overlapping none of the reflective portions 26 and 26C in a plan view. The second substrate 30 may further include a circular polarizer.

In the present embodiment, as illustrated in FIG. 1, in the display region DA of the display device 1, the red subpixel RSP, the green subpixel GSP, and the blue subpixel BSP constituting one pixel PIX are disposed adjacent to each other in the right-left direction in FIG. 1; therefore, the edge cover 23E and the spacer 28 at the right end portion of the red subpixel RSP illustrated in (a) of FIG. 3 are the same as the edge cover 23E and the spacer 28 at the left end portion of the green subpixel GSP illustrated in (b) of FIG. 3, and the edge cover 23E and the spacer 28 at the right end portion of the green subpixel GSP illustrated in (b) of FIG. 3 are the same as the edge cover 23E and the spacer 28 at the left end portion of the blue subpixel BSP illustrated in (c) of FIG. 3.

The reflective portion 26 at the right end portion of the red subpixel RSP illustrated in (a) of FIG. 3 is the same as the reflective portion 26 at the left end portion of the green subpixel GSP illustrated in (b) of FIG. 3. As for the reflective portion 26 at the right end portion of the red subpixel RSP illustrated in (a) of FIG. 3, the reflective surface 26H at the right side is not illustrated, and only the reflective surface 26H at the left side is illustrated. As for the reflective portion 26 at the left end portion of the green subpixel GSP illustrated in (b) of FIG. 3, the reflective surface 26H at the left side is not illustrated, and only the reflective surface 26H at the right side is illustrated. Likewise, the reflective portion 26 at the right end portion of the green subpixel GSP illustrated in (b) of FIG. 3 is the same as the reflective portion 26 at the left end portion of the blue subpixel BSP illustrated in (c) of FIG. 3. As for the reflective portion 26 at the right end portion of the green subpixel GSP illustrated in (b) of FIG. 3, the reflective surface 26H at the right side is not illustrated, and only the reflective surface 26H at the left side is illustrated As for the reflective portion 26 at the left end portion of the blue subpixel BSP illustrated in (c) of FIG. 3, the reflective surface 26H at the left side is not illustrated, and only the reflective surface 26H at the right side is illustrated.

The second electrode 25 is provided to be one layer as a common layer for all the subpixels including the red subpixel RSP illustrated in (a) of FIG. 3, the green subpixel GSP illustrated in (b) of FIG. 3, and the blue subpixel BSP illustrated in (c) of FIG. 3.

The second substrate 30 is one connected substrate, and is provided to face the substrate 2 including the transistors TR.

As described above, the display device 1 includes the gap layer 29 having a certain thickness between the second substrate 30 and the high refractive index layer 27 provided at least in a region overlapping none of the reflective portions 26 and 26C in a plan view, as illustrated in (a) of FIG. 3, (b) of FIG. 3, and (c) of FIG. 3. This makes it possible to enhance the light extraction efficiency in the front direction and suppress the interference unevenness of reflected light L3 and L4 of the light that enters into the display device 1. In addition, the provision of the spacer 28 makes it possible to dispose the second substrate 30 away from the reflective portions 26 and 26C, and thus it is possible to suppress the breakage of the reflective portions 26 and 26C due to the friction between the reflective portions 26 and 26C and the second substrate 30. Further, since the high refractive index layer 27 and the second substrate 30 are provided on the light-emitting element, the reliability can be improved.

Accordingly, the display device 1 may increase the light extraction amount in the front direction of the user and enhance the reliability, and may suppress the breakage of the reflective portions 26 and 26C and the interference unevenness due to the friction with the second substrate 30, without narrowing the light-emitting region or largely reducing the productivity.

On the other hand, in the case of the light extraction structure disclosed in PTL 1 described above, since a gap is provided between the waveguide layer and the sealing member by utilizing the height of the projection and the thickness of the inclined reflective portion provided on the projection, the height of the projection that is formed in such a manner as to cover the end portion of the reflective electrode is necessarily required to be high.

Such a projection having a large height and having an inclined face is generally formed by a photolithography method using a photosensitive material from the viewpoint of productivity or the like. In the photolithography method using a photosensitive material, when the projection is formed to have a large height, the projection is also formed to have a large width, thereby raising a problem that the light-emitting region is narrowed with an increase in width of the projection formed between the adjacent reflective electrodes.

Further, in a case where the projection having such a large height and an inclined face is to be formed by chemical vapor deposition (CVD), a large amount of time is required for film formation due to the large height, and a process of forming a photoresist by the photolithography method and an etching process are additionally required in order to form the inclined face, thereby raising a problem that the productivity is remarkably lowered.

Furthermore, in the case of the light extraction structure described in PTL 1, since the inclined reflective portion and the sealing member are in direct contact with each other, there is a problem that the breakage of the inclined reflective portion due to the friction with the sealing member cannot be prevented.
(a) of FIG. 4, (b) of FIG. 4, (c) of FIG. 4, (d) of FIG. 4, (e) of FIG. 4, (f) of FIG. 4, and (g) of FIG. 4 are diagrams illustrating an example of a manufacturing process of the display device 1 of the first embodiment.

The manufacturing method of the display device 1 includes, as steps of forming the red light-emitting element 5R, the green light-emitting element 5G and the blue light-emitting element 5B, a step of forming a first electrode in which the first electrode 22 for reflecting visible light is formed on the substrate 2 including the transistors TR, i.e., on the surface 2S on the light-emitting element side of the substrate 2 including the transistor TR, as illustrated in (a) of FIG. 4; a step of forming a function layer including a light-emitting layer carried out after the step of forming a first electrode, as illustrated in (b) of FIG. 4; and a step of forming a second electrode in which the second electrode 25 for transmitting visible light carried out after the step of forming a function layer, as illustrated in (c) of FIG. 4. In (b) of FIG. 4, only the step of forming a function layer in which the function layer 24R including the red light-emitting layer is formed in the red subpixel RSP is illustrated, but in the step of forming a function layer, the function layer 24G including the green light-emitting layer is formed in the green subpixel GSP, and the function layer 24B including the blue light-emitting layer is formed in the blue subpixel BSP.

The manufacturing method of the display device 1 further includes a step of forming reflective portions in which formed are the reflective portions 26 and 26C having the reflective surfaces 26H inclined with respect to a surface on the side where the first electrode 22 of the substrate 2 including the transistors TR is provided, i.e., with respect to the surface 2S on the light-emitting element side of the substrate 2 including the transistors TR, as illustrated in (d) of FIG. 4; a step of forming a high refractive index layer in which the high refractive index layer 27 is formed on the second electrode 25 for guiding the light entering from the second electrode 25 side at an angle equal to or greater than the total reflection critical angle, to the reflective surface 26H, and transmitting the light entering at an angle less than the total reflection critical angle, to be carried out after the step of forming a second electrode, as illustrated in (e) of FIG. 4; a step of forming a spacer in which formed is the spacer 28 that forms the gap layer 29 having a certain thickness between the second substrate 30 and the high refractive index layer 27 provided at least in a region overlapping none of the reflective portions 26 and 26C in a plan view and having a refractive index lower than the refractive index of the high refractive index layer 27, and disposes the second substrate 30 away from the reflective portions 26 and 26C, to be carried out after the step of forming a high refractive index layer illustrated in (e) of FIG. 4 and before a step of forming a second substrate illustrated in (g) of FIG. 4, as illustrated in (f) of FIG. 4; and the step of forming a second substrate in which the second substrate 30 is formed to face the surface on the side where the first electrode 22 of the substrate 2 including the transistors TR is provided, i.e., the surface 2S on the light-emitting element side of the substrate 2 including the transistors TR, to be carried out after the step of forming a spacer illustrated in (f) of FIG. 4, as illustrated in (g) of FIG. 4.

In the step of forming a second substrate illustrated in (g) of FIG. 4, a sealing material is preferably provided in the frame region NDA illustrated in FIG. 1, and the second substrate 30 is preferably fixed in the frame region NDA by using the sealing material.

Since the display device 1 of the first embodiment includes the edge cover layer 23E, the manufacturing method of the display device 1 further includes a step of forming an edge cover layer, illustrated in (a) of FIG. 4, in which the edge cover layer 23E covering the end portion of the first electrodes 22 is formed between the step of forming a first electrode and the step of forming a function layer illustrated in (b) of FIG. 4. In the step of forming reflective portions illustrated in (d) of FIG. 4, the reflective portion 26 is preferably formed in such a manner that at least part of the reflective portion 26 overlaps the edge cover layer 23E in a plan view.

Since the display device 1 of the first embodiment further includes the structural body 23K together with the edge cover layer 23E, in the step of forming an edge cover layer illustrated in (a) of FIG. 4, it is preferable to form the structural body 23K, which overlaps part of the function layer including the light-emitting layer in a plan view and is located below the reflective portions 26 and 26C, together with the edge cover layer 23E. Then, in the step of forming reflective portions illustrated in (d) of FIG. 4, the reflective portions 26 and 26C are preferably formed in such a manner that at least part of the reflective portion 26 and at least part of the reflective portion 26C overlap the edge cover layer 23E and the structural body 23K in a plan view.

In the step of forming a spacer illustrated in (f) of FIG. 4, the spacer 28 is preferably formed on the edge cover layer 23E.

Further, it is preferable that the material for forming the high refractive index layer 27 in the step of forming a high refractive index layer illustrated in (e) of FIG. 4 and the material for forming the spacer 28 in the step of forming a spacer illustrated in (f) of FIG. 4 be the same material, and the step of forming a high refractive index layer illustrated in (e) of FIG. 4 and the step of forming a spacer illustrated in (f) of FIG. 4 be the same step By the same step mentioned above, the high refractive index layer 27 and the spacer 28 are simultaneously formed.

As described above, the manufacturing method of the display device 1 may increase the light extraction amount in the front direction of the user and enhance the reliability, and may suppress the breakage of the reflective portions 26 and 26C and the interference unevenness due to the friction with the second substrate 30, without narrowing the light-emitting region or largely reducing the productivity.

As described above, the step of forming a function layer illustrated in (b) of FIG. 4 includes a step of forming a red light-emitting layer included in the step of forming a function layer in which the function layer 24R including the red light-emitting layer is formed in the red subpixel RSP; a step of forming a green light-emitting layer included in the step of forming a function layer in which the function layer 24G including the green light-emitting layer is formed in the green subpixel GSP; and a step of forming a blue light-emitting layer included in the step of forming a function layer in which the function layer 24B including the blue light-emitting layer is formed in the blue subpixel BSP.

As will be described in a second embodiment (see (a) of FIG. 5, (b) of FIG. 5, and (c) of FIG. 5), in a case where a first high refractive index layer 27R, into which light from a red light-emitting layer formed in a red subpixel RSP enters, a second high refractive index layer 27G, into which light from a green light-emitting layer formed in a green subpixel GSP enters, and a third high refractive index layer 27B, into which light from a blue light-emitting layer formed in a blue subpixel BSP enters, are formed of mutually different materials, the step of forming a high refractive index layer illustrated in (e) of FIG. 4 includes a step of forming a first high refractive index layer in which the first high refractive index layer 27R, into which the light from the red light-emitting layer formed in the red subpixel RSP enters, is formed in the red subpixel RSP; a step of forming a second high refractive index layer in which the second high refractive index layer 27G, into which the light from the green light-emitting layer formed in the green subpixel GSP enters, is formed in the green subpixel GSP; and a step of forming a third high refractive index layer in which the third high refractive index layer 27B, into which the light from the blue light-emitting layer formed in the blue subpixel BSP enters, is formed in the blue subpixel BSP.

Even in the above-discussed case, the step of forming a high refractive index layer illustrated in (e) of FIG. 4 and the step of forming a spacer illustrated in (f) of FIG. 4 may be carried out as the same step, and a spacer 28a (see (a) of FIG. 5, (b) of FIG. 5, and (c) of FIG. 5) may be formed of at least one of a layer 27R′ made of the same material as the first high refractive index layer 27R, a layer 27G′ made of the same material as the second high refractive index layer 27G, and a layer 27B′ made of the same material as the third high refractive index layer 27B.

### Second Embodiment

Next, with reference to FIG. 5 to FIG. 8, a second embodiment of the present invention will be described. Display devices 1a and 1b of the present embodiment are different from the above-described first embodiment in that the first high refractive index layer 27R, into which light from the red light-emitting layer formed in the red subpixel RSP enters, the second high refractive index layer 27G, into which light from the green light-emitting layer formed in the green subpixel GSP enters, and the third high refractive index layer 27B, into which light from the blue light-emitting layer formed in the blue subpixel BSP enters, are formed of mutually different materials, and the spacer 28a is formed of at least one of the layer 27R′ made of the same material as the first high refractive index layer 27R, the layer 27G′ made of the same material as the second high refractive index layer 27G, and the layer 27B′ made of the same material as the third high refractive index layer 27B. The others are as described in the first embodiment. For convenience of description, members having the same functions as those illustrated in diagrams of the first embodiment are denoted by the same reference signs, and descriptions thereof are omitted.
(a) of FIG. 5 is a cross-sectional view illustrating a schematic configuration of the red subpixel RSP provided in a display device according to the second embodiment, (b) of FIG. 5 is a cross-sectional view illustrating a schematic configuration of the green subpixel GSP provided in the display device according to the second embodiment, and (c) of FIG. 5 is a cross-sectional view illustrating a schematic configuration of the blue subpixel BSP provided in the display device according to the second embodiment.

The first high refractive index layer 27R, into which the light from the red light-emitting layer formed in the red subpixel RSP illustrated in (a) of FIG. 5 enters, the second high refractive index layer 27G, into which the light from the green light-emitting layer formed in the green subpixel GSP illustrated in (b) of FIG. 5 enters, and the third high refractive index layer 27B, into which the light from the blue light-emitting layer formed in the blue subpixel BSP illustrated in (c) of FIG. 5 enters, are formed of mutually different materials.

In the present embodiment, as illustrated in (a) of FIG. 5, (b) of FIG. 5, and (c) of FIG. 5, the spacer 28a is formed by a layered film of the layer 27R′ made of the same material as the first high refractive index layer 27R, the layer 27G′ made of the same material as the second high refractive index layer 27G, and the layer 27B′ made of the same material as the third high refractive index layer 27B, but is not limited thereto. For example, the spacer 28a may be formed of at least one of the layer 27R′ made of the same material as the first high refractive index layer 27R, the layer 27G′ made of the same material as the second high refractive index layer 27G, and the layer 27B′ made of the same material as the third high refractive index layer 27B.
(a) of FIG. 6 illustrates an example of each light emission spectrum of the red light-emitting layer including Cd-free quantum dots provided in the red subpixel RSP of the display device according to the second embodiment, the green light-emitting layer including Cd-free quantum dots provided in the green subpixel GSP of the display device according to the second embodiment, and the blue light-emitting layer including Cd-free quantum dots provided in the blue subpixel BSP of the display device according to the second embodiment. (b) of FIG. 6 illustrates another example of each light emission spectrum of the red light-emitting layer including Cd-based quantum dots provided in the red subpixel RSP of the display device as a modified example of the second embodiment, the green light-emitting layer including Cd-based quantum dots provided in the green subpixel GSP of the display device as the modified example of the second embodiment, and the blue light-emitting layer including Cd-based quantum dots provided in the blue subpixel BSP of the display device as the modified example of the second embodiment

As depicted in (a) of FIG. 6, the light emission peak wavelength of the red light-emitting layer provided in the red subpixel RSP of the display device according to the second embodiment is about 625 nm, the light emission peak wavelength of the green light-emitting layer provided in the green subpixel GSP of the display device according to the second embodiment is about 550 nm, and the light emission peak wavelength of the blue light-emitting layer provided in the blue subpixel BSP of the display device according to the second embodiment is about 450 nm. As depicted in (a) of FIG. 6, the width of the light emission wavelength range of the blue light-emitting layer is relatively narrow, but the widths of the light emission wavelength ranges of the green light-emitting layer and the red light-emitting layer are relatively wide.

As depicted in (b) of FIG. 6, the light emission peak wavelength of the red light-emitting layer provided in the red subpixel RSP of the display device as the modified example of the second embodiment is about 625 nm, the light emission peak wavelength of the green light-emitting layer provided in the green subpixel GSP of the display device as the modified example of the second embodiment is about 540 nm, and the light emission peak wavelength of the blue light-emitting layer provided in the blue subpixel BSP of the display device as the modified example of the second embodiment is about 475 nm. As depicted in (b) of FIG. 6, the widths of the light emission wavelength ranges of the green light-emitting layer and the red light-emitting layer are relatively narrow, but the width of the light emission wavelength range of the blue light-emitting layer is relatively wide.

FIG. 7 is a diagram illustrating optical transparency characteristics in the visible light region and light absorption characteristics in the visible light region of the first high refractive index layer 27R formed in the red subpixel RSP, the second high refractive index layer 27G formed in the green subpixel GSP and the third high refractive index layer 27B formed in the blue subpixel BSP provided in the display device of the second embodiment, and optical transparency characteristics in the visible light region and light absorption characteristics in the visible light region of the layer 27R′ made of the same material as the first high refractive index layer 27R, the layer 27G′ made of the same material as the second high refractive index layer 27G, and the layer 27B′ made of the same material as the third high refractive index layer 27B constituting the spacer 28a.

As depicted in FIG. 7, the first high refractive index layer 27R and the layer 27R′ made of the same material as the first high refractive index layer 27R are each formed of a photosensitive high refractive index resin containing a first absorption agent that absorbs visible light in a wavelength range of 610 nm or less, and therefore visible light in the wavelength range of 610 nm or less is absorbed from the light emission wavelength range of the red light-emitting layer depicted in (a) of FIG. 6 or (b) of FIG. 6. Accordingly, after the light from the red light-emitting layer having the light emission wavelength range depicted in (a) of FIG. 6 or (b) of FIG. 6 has passed through the first high refractive index layer 27R and the layer 27R′ made of the same material as the first high refractive index layer 27R, the transparency peak wavelength of the light is in a range from 610 nm to 640 nm. The first absorption agent that absorbs visible light in the wavelength range of 610 nm or less refers to an absorption agent that exhibits a visible light absorption peak wavelength of 610 nm or less and absorbs visible light in the wavelength range of 610 nm or less.

As depicted in FIG. 7, the second high refractive index layer 27G and the layer 27G′ made of the same material as the second high refractive index layer 27G are each formed of a photosensitive high refractive index resin containing a second absorption agent that absorbs visible light in a wavelength range of 530 nm or less and a third absorption agent that absorbs visible light in a wavelength range of 560 nm or more; therefore, visible light in the wavelength range of 530 nm or less and visible light in the wavelength range of 560 nm or more are absorbed from the light emission wavelength range of the green light-emitting layer depicted in (a) of FIG. 6 or (b) of FIG. 6. Accordingly, after the light from the green light-emitting layer having the light emission wavelength range depicted in (a) of FIG. 6 or (b) of FIG. 6 has passed through the second high refractive index layer 27G and the layer 27G′ made of the same material as the second high refractive index layer 27G, the transparency peak wavelength of the light is in a range from 530 nm to 560 nm. The second absorption agent that absorbs visible light in the wavelength range of 530 nm or less refers to an absorption agent that exhibits a visible light absorption peak wavelength of 530 nm or less and absorbs visible light in the wavelength range of 530 nm or less. The third absorption agent that absorbs visible light in the wavelength range of 560 nm or more refers to an absorption agent that exhibits a visible light absorption peak wavelength of 560 nm or more and absorbs visible light in the wavelength range of 560 nm or more

As depicted in FIG. 7, the third high refractive index layer 27B and the layer 27B′ made of the same material as the third high refractive index layer 27B are each formed of a photosensitive high refractive index resin containing a fourth absorption agent that absorbs visible light in a wavelength range of 480 nm or more, and therefore visible light in the wavelength range of 480 nm or more is absorbed from the light emission wavelength range of the blue light-emitting layer depicted in (a) of FIG. 6 or (b) of FIG. 6. Accordingly, after the light from the blue light-emitting layer having the light emission wavelength range depicted in (a) of FIG. 6 or (b) of FIG. 6 has passed through the third high refractive index layer 27B and the layer 27B′ made of the same material as the third high refractive index layer 27B, the transparency peak wavelength of the light is in a range from 440 nm to 480 nm. The fourth absorption agent that absorbs visible light in the wavelength range of 480 nm or more refers to an absorption agent that exhibits a visible light absorption peak wavelength of 480 nm or more and absorbs visible light in the wavelength range of 480 nm or more.

As described above, the red subpixel RSP is provided with the first high refractive index layer 27R exhibiting the optical transparency characteristics in the visible light region and the light absorption characteristics in the visible light region, the green subpixel GSP is provided with the second high refractive index layer 27G exhibiting the optical transparency characteristics in the visible light region and the light absorption characteristics in the visible light region, and the blue subpixel BSP is provided with the third high refractive index layer 27B exhibiting the optical transparency characteristics in the visible light region and the light absorption characteristics in the visible light region, whereby the display device capable of display with high color purity may be achieved.

In addition, since the spacer 28a, the first high refractive index layer 27R, the second high refractive index layer 27G, and the third high refractive index layer 27B can absorb approximately two-thirds of external light, it is possible to achieve the display device in which external light reflection is suppressed.

In the present embodiment, since the first high refractive index layer 27R, the second high refractive index layer 27G, and the third high refractive index layer 27B are formed in that order, the spacer 28a is formed by a layered film in which the layer 27R′ made of the same material as the first high refractive index layer 27R, the layer 27G′ made of the same material as the second high refractive index layer 27G, and the layer 27B′ made of the same material as the third high refractive index layer 27B are layered in that order from the side of the substrate 2 including the transistors TR as illustrated in (a) of FIG. 5, (b) of FIG. 5, and (c) of FIG. 5, but the present invention is not limited thereto. Since the order of forming the first high refractive index layer 27R, the second high refractive index layer 27G, and the third high refractive index layer 27B can be appropriately determined, the order of layering the layer 27R′ made of the same material as the first high refractive index layer 27R, the layer 27G′ made of the same material as the second high refractive index layer 27G, and the layer 27B′ made of the same material as the third high refractive index layer 27B in the layered film constituting the spacer 28a is also determined in accordance with the order of forming the first high refractive index layer 27R, the second high refractive index layer 27G, and the third high refractive index layer 27B.

The materials of the first absorption agent that absorbs visible light in the wavelength range of 610 nm or less, the second absorption agent that absorbs visible light in the wavelength range of 530 nm or less, the third absorption agent that absorbs visible light in the wavelength range of 560 nm or more, and the fourth absorption agent that absorbs visible light in the wavelength range of 480 nm or more are not particularly limited as long as the materials can absorb light in a specified wavelength range, and examples of the materials include pigments (metal compounds (oxide, sulfide, sulfates, chromate, and the like)), lake pigments, coloring pigments, organic dyes, dichroic dyes (azo-based, anthraquinone-based, quinophthalone-based, dioxazine-based, and the like), and metal nanoparticles (plasmon absorption).
(a) of FIG. 8 is a plan view illustrating a schematic configuration of a display device 1a according to the second embodiment, and (b) of FIG. 8 is a plan view illustrating a schematic configuration of a display device 1b as a modified example of the second embodiment.

As illustrated in (a) of FIG. 8, the spacer 28a is formed on the edge cover layer 23E covering the end portion of the first electrode 22 along the shape of the edge cover layer 23E in the display device 1a of the second embodiment. In the display device 1a of the second embodiment, since the spacer 28a is formed to cover the entire flat portion of the reflective portion 26 as depicted in (a) of FIG. 5. (b) of FIG. 5, and (c) of FIG. 5, the reflective portion 26C is exposed but the reflective portion 26 is not exposed in (a) of FIG. 8.

As illustrated in (b) of FIG. 8, the spacer 28b is formed on the edge cover layer 23E covering the end portion of the first electrode 22 in a dot shape in the display device 1b as the modified example of the second embodiment. That is, the spacer 28b is provided in the dot shape in four corners of each of the red subpixel RSP, the green subpixel GSP, and the blue subpixel BSP. The spacer 28b is formed of a layered film similar to the layered film of the spacer 28a described above.

### Third Embodiment

Next, a third embodiment of the present invention will be described with reference to FIG. 9. A display device of the present embodiment is different from those of the first and second embodiments in that a reflective portion 26C formed to cover part of a structural body 23K is covered with any of a first high refractive index layer 27R, a second high refractive index layer 27G, and a third high refractive index layer 27B, which are high refractive index layers having visible light absorption characteristics. The others are as described in the first and second embodiments. For convenience of description, members having the same functions as the members illustrated in the diagrams in the first and second embodiments are denoted by the same reference signs, and descriptions thereof will be omitted.
(a) of FIG. 9 is a cross-sectional view illustrating a schematic configuration of a red subpixel RSP provided in the display device according to the third embodiment, (b) of FIG. 9 is a cross-sectional view illustrating a schematic configuration of a green subpixel GSP provided in the display device according to the third embodiment, and (c) of FIG. 9 is a cross-sectional view illustrating a schematic configuration of a blue subpixel BSP provided in the display device according to the third embodiment.

As illustrated in (a) of FIG. 9. (b) of FIG. 9, and (c) of FIG. 9, in the display device according to the third embodiment, the reflective portion 26C having a reflective surface 26H formed to cover part of the structural body 23K is covered with the high refractive index layer. For example, the reflective portion 26C having the reflective surface 26H formed to cover part of the structural body 23K is covered with any of the first high refractive index layer 27R, the second high refractive index layer 27G, and the third high refractive index layer 27B, which are high refractive index layers having visible light absorption characteristics.

According to the above-described configuration, since the reflective portion 26C having the reflective surface 26H is covered with the high refractive index layer material having visible light absorption characteristics, unnecessary external light reflection at the reflective portion 26C may be suppressed and the contrast under external light may be improved in the display device of the third embodiment.

As illustrated in (a) of FIG. 9 and (b) of FIG. 9, a spacer 28′ is formed of the same material as the third high refractive index layer 27B between the red subpixel RSP and the green subpixel GSP; as illustrated in (b) of FIG. 9 and (c) of FIG. 9, a spacer 28″ is formed of the same material as the first high refractive index layer 27R between the green subpixel GSP and the blue subpixel BSP; as illustrated in (c) of FIG. 9 and (a) of FIG. 9, the spacer 28″ is formed of the same material as the second high refractive index layer 27G between the blue subpixel BSP and the red subpixel RSP.

With the above configuration, in the display device according to the third embodiment, it is possible to suppress guiding of light between the subpixels and to suppress color bleeding.

### Fourth Embodiment

Next, a fourth embodiment of the present invention will be described with reference to FIG. 10. A display device of the present embodiment is different from that of the second embodiment described above in that each of a red subpixel RSP, a green subpixel GSP, and a blue subpixel BSP includes a light-emitting element 5W configured to emit white light. Other configurations are as described in the second embodiment. For convenience of explanation, components having the same functions as those described in diagrams of the second embodiment are denoted by the same reference signs, and descriptions thereof may be omitted.
(a) of FIG. 10 is a cross-sectional view illustrating a schematic configuration of the red subpixel RSP provided in the display device according to the fourth embodiment, (b) of FIG. 10 is a cross-sectional view illustrating a schematic configuration of the green subpixel GSP provided in the display device according to the fourth embodiment, and (c) of FIG. 10 is a cross-sectional view illustrating a schematic configuration of the blue subpixel BSP provided in the display device according to the fourth embodiment.

As illustrated in (a) of FIG. 10, (b) of FIG. 10, and (c) of FIG. 10, each of the red subpixel RSP, the green subpixel GSP, and the blue subpixel BSP included in the display device according to the present embodiment includes the light-emitting element 5W configured to emit white light.

Since a first high refractive index layer 27R formed in the red subpixel RSP, a second high refractive index layer 27G formed in the green subpixel GSP, and a third high refractive index layer 27B formed in the blue subpixel BSP each have optical transparency characteristics in the visible light region and light absorption characteristics in the visible light region as depicted in FIG. 7, the first high refractive index layer 27R serves as a red color filter, the second high refractive index layer 27G serves as a green color filter, and the third high refractive index layer 27B serves as a blue color filter. Accordingly, light from the light-emitting element 5W configured to emit white light and provided in the red subpixel RSP is emitted as red light after passing through the first high refractive index layer 27R formed in the red subpixel RSP, light from the light-emitting element 5W configured to emit white light and provided in the green subpixel GSP is emitted as green light after passing through the second high refractive index layer 27G formed in the green subpixel GSP, and light from the light-emitting element 5W configured to emit white light and provided in the blue subpixel BSP is emitted as blue light after passing through the third high refractive index layer 27B formed in the blue subpixel BSP.

In the present embodiment, a function layer 24W including the light-emitting layer provided in the light-emitting element 5W configured to emit white light includes, for example, a layered light-emitting layer in which a blue organic light-emitting layer and a yellow organic light-emitting layer are laminated as the light-emitting layer to achieve white light emission, but the present invention is not limited thereto as long as white light can be emitted. For example, the function layer 24W including the light-emitting layer provided in the light-emitting element 5W configured to emit white light may include, as light-emitting layers, a red light-emitting layer including quantum dots, a green light-emitting layer including quantum dots, and a blue light-emitting layer including quantum dots, or may include a red organic light-emitting layer, a green organic light-emitting layer, and a blue organic light-emitting layer.

As described above, also in the case where the light-emitting element 5W configured to emit white light is provided, the display device capable of displaying with high color purity may be achieved by providing the first high refractive index layer 27R exhibiting the above-discussed optical transparency characteristics and light absorption characteristics in the red subpixel RSP, the second high refractive index layer 27G exhibiting the above-discussed optical transparency characteristics and light absorption characteristics in the green subpixel GSP, and the third high refractive index layer 27B exhibiting the above-discussed optical transparency characteristics and light absorption characteristics in the blue subpixel BSP.

In addition, since a spacer 28a, the first high refractive index layer 27R, the second high refractive index layer 27G, and the third high refractive index layer 27B can absorb approximately two-thirds of external light, it is possible to achieve the display device in which external light reflection is suppressed.

### Fifth Embodiment

Next, a fifth embodiment of the present invention will be described with reference to FIG. 11 and FIG. 12. A display device of the present embodiment is different from those of the first to fourth embodiments described above in that both a first high refractive index layer 27M provided in a red subpixel RSP and a third high refractive index layer 27M provided in a blue subpixel BSP are formed of a photosensitive high refractive index resin containing a fifth absorption agent that absorbs visible light in a wavelength range from 530 nm to 560 nm, a second high refractive index layer 27G provided in a green subpixel GSP is formed of a photosensitive high refractive index resin containing a second absorption agent that absorbs visible light in a wavelength range of 530 nm or less and a third absorption agent that absorbs visible light in a wavelength range of 560 nm or more, and a spacer 28c is formed by at least one of a layer 27M′ made of the same material as that of either the first high refractive index layer 27M or the third high refractive index layer 27M and a layer 27G′ made of the same material as that of the second high refractive index layer 27G. The others are as described in the first to fourth embodiments. For convenience of description, members having the same functions as those of the members illustrated in drawings of the first to fourth embodiments are denoted by the same reference signs, and descriptions thereof may be omitted.
(a) of FIG. 11 is a cross-sectional view illustrating a schematic configuration of the red subpixel RSP provided in the display device according to the fifth embodiment, (b) of FIG. 11 is a cross-sectional view illustrating a schematic configuration of the green subpixel GSP provided in the display device according to the fifth embodiment, and (c) of FIG. 11 is a cross-sectional view illustrating a schematic configuration of the blue subpixel BSP provided in the display device according to the fifth embodiment.

Both the first high refractive index layer 27M provided in the red subpixel RSP illustrated in (a) of FIG. 11 and the third high refractive index layer 27M provided in the blue subpixel BSP illustrated in (c) of FIG. 11 are formed of a photosensitive high refractive index resin containing the fifth absorption agent that absorbs visible light in the wavelength range from 530 nm to 560 nm, and the second high refractive index layer 27G provided in the green subpixel GSP illustrated in (b) of FIG. 11 is formed of a photosensitive high refractive index resin containing the second absorption agent that absorbs visible light in the wavelength range of 530 nm or less and the third absorption agent that absorbs visible light in the wavelength range of 560 nm or more.

In the present embodiment, as illustrated in (a) of FIG. 11, (b) of FIG. 11, and (c) of FIG. 11, a case will be described as an example in which the spacer 28c is formed by a layered film of the layer 27M′ made of the same material as that of either the first high refractive index layer 27M or the third high refractive index layer 27M and the layer 27G made of the same material as that of the second high refractive index layer 27G, but the present invention is not limited thereto. The spacer 28c may be formed of at least one of the layer 27M′ made of the same material as that of either the first high refractive index layer 27M or the third high refractive index layer 27M and the layer 27G′ made of the same material as that of the second high refractive index layer 27G.

FIG. 12 is a diagram illustrating visible light optical transparency characteristics and visible light absorption characteristics of the first high refractive index layer 27M formed in the red subpixel RSP, the second high refractive index layer 27G formed in the green subpixel GSP and the third high refractive index layer 27M formed in the blue subpixel BSP provided in the display device of the fifth embodiment illustrated in FIG. 11, and the above-mentioned characteristics of the layer 27M′ made of the same material as the first high refractive index layer 27M and third high refractive index layer 27M and the layer 27G′ made of the same material as the second high refractive index layer 27G constituting the spacer 28c.

As depicted in FIG. 12, the first high refractive index layer 27M and the layer 27M′ made of the same material as the first high refractive index layer 27M are each formed of a photosensitive high refractive index resin containing the fifth absorption agent that absorbs visible light in the wavelength range from 530 nm to 560 nm, and therefore visible light in the wavelength range from 530 nm to 560 nm is absorbed from the light emission wavelength range of the red light-emitting layer depicted in (a) of FIG. 6 or (b) of FIG. 6. Accordingly, after the light from the red light-emitting layer having the light emission wavelength range depicted in (a) of FIG. 6 or (b) of FIG. 6 has passed through the first high refractive index layer 27M and the layer 27M′ made of the same material as the first high refractive index layer 27M, the transparency peak wavelength of the light is in a range from 610 nm to 640 nm. The fifth absorption agent that absorbs visible light in the wavelength range from 530 nm to 560 nm refers to an absorption agent that exhibits a visible light absorption peak wavelength in a range from 530 nm to 560 nm, and absorbs visible light in the wavelength range from 530 nm to 560 nm.

As depicted in FIG. 12, the second high refractive index layer 27G and the layer 27G′ made of the same material as the second high refractive index layer 27G are each formed of a photosensitive high refractive index resin containing the second absorption agent that absorbs visible light in the wavelength range of 530 nm or less and the third absorption agent that absorbs visible light in the wavelength range of 560 nm or more, and therefore visible light in the wavelength range of 530 nm or less and visible light in the wavelength range of 560 nm or more are absorbed from the light emission wavelength range of the green light-emitting layer depicted in (a) of FIG. 6 or (b) of FIG. 6. Accordingly, after the light from the green light-emitting layer having the light emission wavelength range depicted in (a) of FIG. 6 or (b) of FIG. 6 has passed through the second high refractive index layer 27G and the layer 27G′ made of the same material as the second high refractive index layer 27G, the transparency peak wavelength of the light is in a range from 530 nm to 560 nm.

As depicted in FIG. 12, the third high refractive index layer 27M and the layer 27M′ made of the same material as the third high refractive index layer 27M are each formed of a photosensitive high refractive index resin containing the fifth absorption agent that absorbs visible light in the wavelength range from 530 nm to 560 nm, and therefore visible light in the wavelength range from 530 nm to 560 nm is absorbed from the light emission wavelength range of the blue light-emitting layer depicted in (a) of FIG. 6 or (b) of FIG. 6. Accordingly, after the light from the blue light-emitting layer having the light emission wavelength range depicted in (a) of FIG. 6 or (b) of FIG. 6 has passed through the third high refractive index layer 27M and the layer 27M′ made of the same material as the third high refractive index layer 27M, the transparency peak wavelength of the light is in a range from 440 nm to 480 nm.

As described above, the red subpixel RSP is provided with the first high refractive index layer 27M exhibiting the above-discussed visible light optical transparency characteristics and visible light absorption characteristics, the green subpixel GSP is provided with the second high refractive index layer 27G exhibiting the above-discussed visible light optical transparency characteristics and visible light absorption characteristics, and the blue subpixel BSP is provided with the third high refractive index layer 27M exhibiting the above-discussed visible light optical transparency characteristics and visible light absorption characteristics, whereby the display device capable of displaying with high color purity may be achieved.

Since the first high refractive index layer 27M formed in the red subpixel RSP and the third high refractive index layer 27M formed in the blue subpixel BSP are made of the same material, the first high refractive index layer 27M formed in the red subpixel RSP and the third high refractive index layer 27M formed in the blue subpixel BSP can be formed at the same time, whereby the manufacturing manpower for the high refractive index layers respectively formed in the red subpixel RSP, the green subpixel GSP, and the blue subpixel BSP may be reduced.

In addition, since the spacer 28c, the first high refractive index layer 27M, and the third high refractive index layer 27M can absorb approximately two-thirds of green external light having a high luminosity efficiency factor, it is possible to achieve the display device in which external light reflection is suppressed.

In the present embodiment, since the first high refractive index layer 27M, the third high refractive index layer 27M, and the second high refractive index layer 27G are formed in that order, the spacer 28c is formed by a layered film in which the layer 27M′ made of the same material as the first high refractive index layer 27M and the third high refractive index layer 27M, and the layer 27G′ made of the same material as the second high refractive index layer 27G are layered in that order from the side of the substrate 2 including the transistors TR as illustrated in (a) of FIG. 11, (b) of FIG. 11, and (c) of FIG. 11, but the present invention is not limited thereto. Since the order of forming the first high refractive index layer 27M, the third high refractive index layer 27M, and the second high refractive index layer 27G can be appropriately determined, the order of layering the layer 27M′ made of the same material as the first high refractive index layer 27M and the third high refractive index layer 27M, and the layer 27G′ made of the same material as the second high refractive index layer 27G in the layered film constituting the spacer 28c is also determined in accordance with the order of forming the first high refractive index layer 27M, the third high refractive index layer 27M, and the second high refractive index layer 27G.

The material of the fifth absorption agent that absorbs visible light in the wavelength range from 530 nm to 560 nm is not particularly limited as long as the material can absorb visible light in a specified wavelength range, and examples of the material include pigments (metal compounds (oxide, sulfide, sulfates, chromate, and the like)), lake pigments, coloring pigments, organic dyes, dichroic dyes (azo-based, anthraquinone-based, quinophthalone-based, dioxazine-based, and the like), and metal nanoparticles (plasmon absorption).

### Sixth Embodiment

Next, a sixth embodiment of the present invention will be described with reference to FIG. 13 and FIG. 14. A display device of the present embodiment is different from those of the first to fifth embodiments described above in that both a first high refractive index layer 27M provided in a red subpixel RSP and a third high refractive index layer 27M provided in a blue subpixel BSP are formed of a photosensitive high refractive index resin containing a fifth absorption agent that absorbs visible light in a wavelength range from 530 nm to 560 nm, a second high refractive index layer 27 provided in a green subpixel GSP is formed of a photosensitive high refractive index resin containing no absorption agent in the visible light region, and a spacer 28d is formed by at least one of a layer 27M′ made of the same material as that of either the first high refractive index layer 27M or the third high refractive index layer 27M and a layer 27′ made of the same material as that of the second high refractive index layer 27. The others are as described in the first to fifth embodiments. For convenience of explanation, components having the same functions as those described in diagrams of the first to fifth embodiments are denoted by the same reference signs, and descriptions thereof may be omitted.
(a) of FIG. 13 is a cross-sectional view illustrating a schematic configuration of the red subpixel RSP provided in the display device according to the sixth embodiment, (b) of FIG. 13 is a cross-sectional view illustrating a schematic configuration of the green subpixel GSP provided in the display device according to the sixth embodiment, and (c) of FIG. 13 is a cross-sectional view illustrating a schematic configuration of the blue subpixel BSP provided in the display device according to the sixth embodiment.

Both the first high refractive index layer 27M provided in the red subpixel RSP illustrated in (a) of FIG. 13 and the third high refractive index layer 27M provided in the blue subpixel BSP illustrated in (c) of FIG. 13 are formed of a photosensitive high refractive index resin containing the fifth absorption agent that absorbs visible light in the wavelength range from 530 nm to 560 nm, and the second high refractive index layer 27 provided in the green subpixel GSP illustrated in (b) of FIG. 13 is formed of a photosensitive high refractive index resin containing no visible light absorption agent.

In the present embodiment, as illustrated in (a) of FIG. 13, (b) of FIG. 13, and (c) of FIG. 13, a case will be described as an example in which the spacer 28d is formed by a layered film of the layer 27M′ made of the same material as that of either the first high refractive index layer 27M or the third high refractive index layer 27M and the layer 27′ made of the same material as that of the second high refractive index layer 27, but the present invention is not limited thereto. The spacer 28d may be formed by at least one of the layer 27M′ made of the same material as that of either the first high refractive index layer 27M or the third high refractive index layer 27M, and the layer 27′ made of the same material as that of the second high refractive index layer 27.

FIG. 14 is a diagram illustrating visible light optical transparency characteristics and visible light absorption characteristics of the first high refractive index layer 27M formed in the red subpixel RSP, the second high refractive index layer 27 formed in the green subpixel GSP and the third high refractive index layer 27M formed in the blue subpixel BSP provided in the display device of the sixth embodiment illustrated in FIG. 13, and the above-mentioned characteristics of the layer 27M′ made of the same material as the first high refractive index layer 27M and third high refractive index layer 27M and the layer 27′ made of the same material as the second high refractive index layer 27 constituting the spacer 28d.

As depicted in FIG. 14, the first high refractive index layer 27M and the layer 27M′ made of the same material as the first high refractive index layer 27M are each formed of a photosensitive high refractive index resin containing the fifth absorption agent that absorbs visible light in the wavelength range from 530 nm to 560 nm, and therefore visible light in the wavelength range from 530 nm to 560 nm is absorbed from the light emission wavelength range of the red light-emitting layer depicted in (a) of FIG. 6 or (b) of FIG. 6. Accordingly, after the light from the red light-emitting layer having the light emission wavelength range depicted in (a) of FIG. 6 or (b) of FIG. 6 has passed through the first high refractive index layer 27M and the layer 27M′ made of the same material as the first high refractive index layer 27M, the transparency peak wavelength of the light is in a range from 610 nm to 640 nm.

As depicted in FIG. 14, since the second high refractive index layer 27 and the layer 27′ made of the same material as the second high refractive index layer 27 are each formed of a photosensitive high refractive index resin containing no visible light absorption agent, no absorption occurs in any region of the light emission wavelength range of the green light-emitting layer depicted in (a) of FIG. 6 or (b) of FIG. 6. Accordingly, after the light from the green light-emitting layer having the light emission wavelength range depicted in (a) of FIG. 6 or (b) of FIG. 6 has passed through the second high refractive index layer 27 and the layer 27′ made of the same material as the second high refractive index layer 27, the transparency peak wavelength of the light does not change.

As depicted in FIG. 14, the third high refractive index layer 27M and the layer 27M′ made of the same material as the third high refractive index layer 27M are each formed of a photosensitive high refractive index resin containing the fifth absorption agent that absorbs visible light in the wavelength range from 530 nm to 560 nm, and therefore visible light in the wavelength range from 530 nm to 560 nm is absorbed from the light emission wavelength range of the blue light-emitting layer depicted in (a) of FIG. 6 or (b) of FIG. 6. Accordingly, after the light from the blue light-emitting layer having the light emission wavelength range depicted in (a) of FIG. 6 or (b) of FIG. 6 has passed through the third high refractive index layer 27M and the layer 27M′ made of the same material as the third high refractive index layer 27M, the transparency peak wavelength of the light is in a range from 440 nm to 480 nm.

As described above, the red subpixel RSP is provided with the first high refractive index layer 27M exhibiting the above-discussed visible light optical transparency characteristics and visible light absorption characteristics, and the blue subpixel BSP is provided with the third high refractive index layer 27M exhibiting the above-discussed visible light optical transparency characteristics and visible light absorption characteristics, whereby the display device capable of displaying with high color purity may be achieved.

Since the first high refractive index layer 27M formed in the red subpixel RSP and the third high refractive index layer 27M formed in the blue subpixel BSP are made of the same material, the first high refractive index layer 27M formed in the red subpixel RSP and the third high refractive index layer 27M formed in the blue subpixel BSP can be formed at the same time, whereby the manufacturing manpower for the high refractive index layers respectively formed in the red subpixel RSP, the green subpixel GSP, and the blue subpixel BSP may be reduced.

In addition, since the spacer 28d, the first high refractive index layer 27M, and the third high refractive index layer 27M can absorb approximately two-thirds of green external light having a high luminosity efficiency factor, it is possible to achieve the display device in which external light reflection is suppressed.

In the present embodiment, since the first high refractive index layer 27M, the third high refractive index layer 27M, and the second high refractive index layer 27 are formed in that order, the spacer 28d is formed by a layered film in which the layer 27M′ made of the same material as the first high refractive index layer 27M and third high refractive index layer 27M and the layer 27′ made of the same material as the second high refractive index layer 27 are layered in that order from the side of the substrate 2 including the transistors TR as illustrated in (a) of FIG. 13, (b) of FIG. 13, and (c) of FIG. 13, but the present invention is not limited thereto. Since the order of forming the first high refractive index layer 27M, the third high refractive index layer 27M, and the second high refractive index layer 27 can be appropriately determined, the order of layering the layer 27M′ made of the same material as the first high refractive index layer 27M and the third high refractive index layer 27M, and the layer 27′ made of the same material as the second high refractive index layer 27 in the layered film constituting the spacer 28d is also determined in accordance with the order of forming the first high refractive index layer 27M, the third high refractive index layer 27M, and the second high refractive index layer 27.

### Seventh Embodiment

Next, a seventh embodiment of the present invention will be described with reference to FIG. 15 to FIG. 17. A display device 1e of the present embodiment is different from the display devices of the first to sixth embodiments in that a first high refractive index layer provided in a red subpixel RSP is formed by a layered film of a first high refractive index resin layer 27M and a second high refractive index resin layer 27Y, a second high refractive index layer provided in a green subpixel GSP is formed by a layered film of the second high refractive index resin layer 27Y and a third high refractive index resin layer 27C, a third high refractive index layer provided in a blue subpixel BSP is formed by a layered film of the first high refractive index resin layer 27M and the third high refractive index resin layer 27C, a spacer 28f provided on an edge cover layer 23E defining the red subpixel RSP and the green subpixel GSP is formed of a layer 27Y′ made of the same material as the second high refractive index resin layer 27Y, a spacer 28g provided on the edge cover layer 23E defining the green subpixel GSP and the blue subpixel BSP is formed of a layer 27C′ made of the same material as the third high refractive index resin layer 27C, and a spacer 28e provided on the edge cover layer 23E defining the blue subpixel BSP and the red subpixel RSP is formed of a layer 27M′ made of the same material as the first high refractive index resin layer 27M. The others are as described in the first to sixth embodiments. For convenience of description, members having the same functions as those of the members described in drawings of the first to sixth embodiments are denoted by the same reference signs, and description thereof is omitted.
(a) of FIG. 15 is a cross-sectional view illustrating a schematic configuration of the red subpixel RSP provided in the display device according to the seventh embodiment, (b) of FIG. 15 is a cross-sectional view illustrating a schematic configuration of the green subpixel GSP provided in the display device according to the seventh embodiment, and (c) of FIG. 15 is a cross-sectional view illustrating a schematic configuration of the blue subpixel BSP provided in the display device according to the seventh embodiment.

FIG. 16 is a plan view illustrating a schematic configuration of the display device 1c according to the seventh embodiment.

FIG. 17 is a diagram depicting visible light optical transparency characteristics and visible light absorption characteristics of the first high refractive index resin layer 27M, the second high refractive index resin layer 27Y, the third high refractive index resin layer 27C, the layer 27M′ made of the same material as the first high refractive index resin layer 27M, the layer 27Y′ made of the same material as the second high refractive index resin layer 27Y, and the layer 27C′ made of the same material as the third high refractive index resin layer 27C, which are provided in the display device of the seventh embodiment illustrated in FIG. 15 and FIG. 16.

As illustrated in (a) of FIG. 15 and FIG. 17, in the display device 1c of the present embodiment, the first high refractive index layer provided in the red subpixel RSP is formed by the layered film of the first high refractive index resin layer 27M made of a photosensitive high refractive index resin containing a fifth absorption agent that absorbs visible light in a wavelength range from 530 nm to 560 nm, and the second high refractive index resin layer 27Y made of a photosensitive high refractive index resin containing a sixth absorption agent that absorbs visible light in a wavelength range of 480 nm or less.

As illustrated in (b) of FIG. 15 and FIG. 17, in the display device 1c of the present embodiment, the second high refractive index layer provided in the green subpixel GSP is formed by the layered film of the second high refractive index resin layer 27Y made of the photosensitive high refractive index resin containing the sixth absorption agent that absorbs visible light in the wavelength range of 480 nm or less, and the third high refractive index resin layer 27C made of a photosensitive high refractive index resin containing a seventh absorption agent that absorbs visible light in a wavelength range of 610 nm or more.

As illustrated in (c) of FIG. 15 and FIG. 17, in the display device 1c of the present embodiment, the third high refractive index layer provided in the blue subpixel BSP is formed by the layered film of the first high refractive index resin layer 27M made of the photosensitive high refractive index resin containing the fifth absorption agent that absorbs visible light in the wavelength range from 530 nm to 560 nm, and the third high refractive index resin layer 27C made of the photosensitive high refractive index resin containing the seventh absorption agent that absorbs visible light in the wavelength range of 610 nm or more.

As illustrated in (a) of FIG. 15, (b) of FIG. 15, (c) of FIG. 15, and FIG. 16, the spacer 28f provided on the edge cover layer 23E defining the red subpixel RSP and the green subpixel GSP is formed of the layer 27Y′ made of the same material as the second high refractive index resin layer 27Y, the spacer 28g provided on the edge cover layer 23E defining the green subpixel GSP and the blue subpixel BSP is formed of the layer 27C′ made of the same material as the third high refractive index resin layer 27C, and the spacer 28e provided on the edge cover layer 23E defining the blue subpixel BSP and the red subpixel RSP is formed of the layer 27M′ made of the same material as the first high refractive index resin layer 27M.

As illustrated in (a) of FIG. 15, in the display device 1c of the present embodiment, the first high refractive index layer provided in the red subpixel RSP is formed of the layered film of the first high refractive index resin layer 27M and the second high refractive index resin layer 27Y. Accordingly, after the light from the red light-emitting layer having the light emission wavelength range depicted in (a) of FIG. 6 or (b) of FIG. 6 has passed through the layered film of the first high refractive index resin layer 27M and the second high refractive index resin layer 27Y, the transparency peak wavelength of the light is in a range from 610 nm to 640 nm.

As illustrated in (b) of FIG. 15, in the display device 1c of the present embodiment, the second high refractive index layer provided in the green subpixel GSP is formed of the layered film of the second high refractive index resin layer 27Y and the third high refractive index resin layer 27C. After the light from the green light-emitting layer having the light emission wavelength range depicted in (a) of FIG. 6 or (b) of FIG. 6 has passed through the layered film of the second high refractive index resin layer 27Y and the third high refractive index resin layer 27C, the transparency peak wavelength of the light is in a range from 530 nm to 560 nm.

As illustrated in (c) of FIG. 15, in the display device 1c of the present embodiment, the third high refractive index layer provided in the blue subpixel BSP is formed of the layered film of the first high refractive index resin layer 27M and the third high refractive index resin layer 27C. Accordingly, after the light from the blue light-emitting layer having the light emission wavelength range depicted in (a) of FIG. 6 or (b) of FIG. 6 has passed through the layered film of the first high refractive index resin layer 27M and the third high refractive index resin layer 27C, the transparency peak wavelength of the light is in a range from 440 nm to 480 nm.

The materials of the sixth absorption agent that absorbs visible light in the wavelength range of 480 nm or less and the seventh absorption agent that absorbs visible light in the wavelength range of 610 nm or more are not particularly limited as long as the materials can absorb visible light in a specified wavelength range, and examples of the materials include pigments (metal compounds (oxide, sulfide, sulfates, chromate, and the like)), lake pigments, coloring pigments, organic dyes, dichroic dyes (azo-based, anthraquinone-based, quinophthalone-based, dioxazine-based, and the like), and metal nanoparticles (plasmon absorption)

As described above, the red subpixel RSP is provided with the layered film of the first high refractive index resin layer 27M and the second high refractive index resin layer 27Y, the green subpixel GSP is provided with the layered film of the second high refractive index resin layer 27Y and the third high refractive index resin layer 27C, and the blue subpixel BSP is provided with the layered film of the first high refractive index resin layer 27M and the third high refractive index resin layer 27C, whereby the display device capable of displaying with high color purity may be achieved.

The layered film provided in the red subpixel RSP and formed of the first high refractive index resin layer 27M and the second high refractive index resin layer 27Y, the layered film provided in the green subpixel GSP and formed of the second high refractive index resin layer 27Y and the third high refractive index resin layer 27C, the layered film provided in the blue subpixel BSP and formed of the first high refractive index resin layer 27M and the third high refractive index resin layer 27C, the spacer 28e formed by the layer 27M′ made of the same material as the first high refractive index resin layer 27M, the spacer 28f formed by the layer 27Y′ made of the same material as the second high refractive index resin layer 27Y, and the spacer 28g formed by the layer 27C′ made of the same material as the third high refractive index resin layer 27C are provide, whereby the display device in which external light reflection is suppressed may be achieved.

### Eighth Embodiment

Next, with reference to FIG. 18 and FIG. 19, an eighth embodiment of the present invention will be described. A display device of the present embodiment is different from those of the first to seventh embodiments in that edge cover layers 23′ and 23″ cover an end portion of the first electrode 22 and are also formed in one subpixel. The others are as described in the first to seventh embodiments. For convenience of description, members having the same functions as those of the members described in drawings of the first to seventh embodiments are denoted by the same reference signs, and description thereof will be omitted.
(a) of FIG. 18 is a plan view illustrating an example of a shape of a high refractive index layer 27′ provided for each subpixel in the display device of the eighth embodiment, (b) of FIG. 18 is a plan view illustrating an example of a shape of the high refractive index layer 27′ provided for each subpixel in the display device as a first modified example of the eighth embodiment, and (c) of FIG. 18 is a plan view illustrating an example of a shape of the high refractive index layer 27′ provided for each subpixel in the display device as a second modified example of the eighth embodiment.

As illustrated in (a) of FIG. 18, (b) of FIG. 18, and (c) of FIG. 18, the edge cover layer 23′ covers the end portion of the first electrode 22 and is also formed in one subpixel. Although only a red subpixel RSP is illustrated here, the same applies to a green subpixel GSP and a blue subpixel BSP.

As depicted in (a) of FIG. 18, (b) of FIG. 18 and (c) of FIG. 18, the edge cover layer 23′ has one connected opening, and the high refractive index layer 27′ is formed in the one connected opening. Thus, the high refractive index layer 27′ is one connected layer in each of the red subpixel RSP, the green subpixel GSP and the blue subpixel BSP.

In the above configuration, the high refractive index layer 27′ may be easily formed by being applied, and for example, the reflective surfaces 26H of the reflective portions 26 and 26C may be reliably covered. Since the high refractive index layer 27′ is one connected layer having a large contact area with the lower face, peeling or the like is unlikely to occur. Furthermore, the area of the reflective surface 26H per subpixel can be increased, and thus the front luminance can be increased.
(a) of FIG. 19 is a plan view illustrating an example of a shape of a high refractive index layer 27″ provided for each subpixel in the display device as a third modified example of the eighth embodiment, and (b) of FIG. 19 is a plan view illustrating an example of a shape of the high refractive index layer 27″ provided for each subpixel of the display device as a fourth modified example of the eighth embodiment.

As illustrated in (a) of FIG. 19 and (b) of FIG. 19, the edge cover layer 23″ covers the end portion of the first electrode 22 and is also formed in one subpixel. Although only the red subpixel RSP is illustrated here, the same applies to the green subpixel GSP and the blue subpixel BSP.

As depicted in (a) of FIG. 19 and (b) of FIG. 19, the edge cover layer 23″ has a plurality of openings formed in a dot shape, and the high refractive index layer 27″ is formed in each of the plurality of openings formed in the dot shape as mentioned above.

### Supplement

### First Aspect

A display device including:

a first substrate;

a subpixel including a light-emitting element in which a first electrode configured to reflect visible light, a function layer including a light-emitting layer, and a second electrode configured to transmit visible light are provided on the first substrate in that order from the first substrate side;

a reflective portion provided in part of the subpixel and having a reflective surface inclined with respect to a surface on the light-emitting element side of the first substrate;

a high refractive index layer that is provided on the second electrode, guides light entering from the second electrode side at an angle equal to or greater than a total reflection critical angle, to the reflective surface, and transmits light entering at an angle less than the total reflection critical angle;

a second substrate provided to face the surface on the light-emitting element side of the first substrate; and

a spacer configured to form a gap layer having a certain thickness between the second substrate and the high refractive index layer provided at least in a region not overlapping the reflective portion in a plan view, and dispose the second substrate away from the reflective portion,

wherein a refractive index of the high refractive index layer is higher than a refractive index of the gap layer.

### Second Aspect

The display device according to the first aspect, wherein the reflective portion is provided above the function layer including the light-emitting layer.

### Third Aspect

The display device according to the first or second aspect, wherein the reflective surface is provided on a side surface of the high refractive index layer.

### Fourth Aspect

The display device according to any one of the first to third aspects, wherein a difference between the refractive index of the high refractive index layer and the refractive index of the gap layer is larger than a difference between an average refractive index of the first electrode, the function layer including the light-emitting layer and the second electrode, and the refractive index of the high refractive index layer.

### Fifth Aspect

The display device according to any one of the first to fourth aspects, wherein the average refractive index of the first electrode, the function layer including the light-emitting layer, and the second electrode is higher than the refractive index of the high refractive index layer.

### Sixth Aspect

The display device according to any one of the first to fifth aspects, wherein the reflective surface includes a metal material that reflects visible light.

### Seventh Aspect

The display device according to any one of the first to sixth aspects,

wherein the reflective portion includes a conductive material, and is formed on the second electrode to be in contact with the second electrode.

### Eighth Aspect

The display device according to any one of the first to sixth aspects, wherein the reflective portion includes a conductive material, and is formed between the second electrode and the function layer including the light-emitting layer to be in contact with the second electrode and the function layer including the light-emitting layer.

### Ninth Aspect

The display device according to any one of the first to eighth aspects,

wherein the reflective portion includes a light scattering agent.

### Tenth Aspect

The display device according to any one of the first to ninth aspects,

wherein the above-mentioned certain thickness of the gap layer is in a range from 1 μm to 10 μm.

### Eleventh Aspect

The display device according to any one of the first to tenth aspects, further including an edge cover layer covering an end portion of the first electrode,

wherein the spacer is formed on the edge cover layer along a shape of the edge cover layer.

### Twelfth Aspect

The display device according to any one of the first to tenth aspects, further including an edge cover layer covering an end portion of the first electrode,

wherein the spacer is formed in a dot shape on the edge cover layer.

### Thirteenth Aspect

The display device according to any one of the first to twelfth aspects, further including an edge cover layer covering an end portion of the first electrode,

wherein at least part of the reflective portion overlaps the edge cover layer in a plan view.

### Fourteenth Aspect

The display device according to the thirteenth aspect, wherein

the edge cover layer includes an inclined face inclined with respect to the surface on the light-emitting element side of the first substrate, and

the reflective surface of the reflective portion is formed along the inclined face.

### Fifteenth Aspect

The display device according to any one of the first to twelfth aspects, further including a structural body that overlaps part of the function layer including the light-emitting layer in a plan view and is provided below the reflective portion,

wherein at least part of the reflective portion overlaps the structural body in the plan view.

### Sixteenth Aspect

The display device according to the fifteenth aspect, wherein

the structural body includes an inclined face inclined with respect to the surface on the light-emitting element side of the first substrate, and

the reflective surface of the reflective portion is formed along the inclined face.

### Seventeenth Aspect

The display device according to any one of the first to twelfth aspects, further including:

a structural body that overlaps part of the function layer including the light-emitting layer in a plan view and is provided below the reflective portion; and

an edge cover layer covering an end portion of the first electrode, wherein at least part of the reflective portion overlaps the edge cover layer and the structural body in the plan view.

### Eighteenth Aspect

The display device according to the seventeenth aspect, wherein

the edge cover layer and the structural body each include an inclined face inclined with respect to the surface on the light-emitting element side of the first substrate, and

the reflective surface of the reflective portion is formed along the inclined face.

### Nineteenth Aspect

The display device according to the seventeenth or eighteenth aspect,

wherein a maximum height of the edge cover layer is higher than a maximum height of the structural body by a thickness of the function layer including the light-emitting layer.

### Twentieth Aspect

The display device according to any one of the seventeenth to nineteenth aspects, wherein the edge cover layer and the structural body are formed of an identical material.

### Twenty-First Aspect

The display device according to any one of the fifteenth to twentieth aspects, wherein the reflective portion formed to cover part of the structural body is covered with the high refractive index layer.

### Twenty-Second Aspect

The display device according to any one of the first to twenty-first aspects, wherein the gap layer is filled with a low refractive index medium having a refractive index lower than the refractive index of the high refractive index layer.

### Twenty-Third Aspect

The display device according to the twenty-second aspect, wherein the low refractive index medium includes at least one of a resin with a refractive index lower than the refractive index of the high refractive index layer, a hollow bead with a refractive index lower than the refractive index of the high refractive index layer, and air.

### Twenty-Fourth Aspect

The display device according to any one of the first to twenty-third aspects, wherein the high refractive index layer is one connected layer in the subpixel.

### Twenty-Fifth Aspect

The display device according to any one of the first to twenty-fourth aspects, wherein the second substrate is a glass substrate or a non-flexible resin substrate.

### Twenty-Sixth Aspect

The display device according to any one of the first to twenty-fifth aspects, wherein the second substrate further includes a circular polarizer.

### Twenty-Seventh Aspect

The display device according to any one of the first to twenty-sixth aspects, wherein

a plurality of the subpixels are provided,

the plurality of subpixels include a first subpixel, a second subpixel, and a third subpixel,

the first subpixel is provided with, as the light-emitting element, a first light-emitting element including the first electrode, a function layer including a first light-emitting layer as the light-emitting layer, and the second electrode,

the second subpixel is provided with, as the light-emitting element, a second light-emitting element including the first electrode, a function layer including a second light-emitting layer as the light-emitting layer, and the second electrode,

the third subpixel is provided with, as the light-emitting element, a third light-emitting element including the first electrode, a function layer including a third light-emitting layer as the light-emitting layer, and the second electrode,

a light emission peak wavelength emitted by the first light-emitting layer is longer than a light emission peak wavelength emitted by the second light-emitting layer,

the light emission peak wavelength emitted by the second light-emitting layer is longer than a light emission peak wavelength emitted by the third light-emitting layer,

a first high refractive index layer is provided as the high refractive index layer on the second electrode of the first subpixel,

a second high refractive index layer is provided as the high refractive index layer on the second electrode of the second subpixel, and

a third high refractive index layer is provided as the high refractive index layer on the second electrode of the third subpixel.

### Twenty-Eighth Aspect

The display device according to the twenty-seventh aspect, wherein the first high refractive index layer, the second high refractive index layer, the third high refractive index layer, and the spacer are each formed of a high refractive index resin made of an identical material.

### Twenty-Ninth Aspect

The display device according to the twenty-seventh aspect, wherein

the first light-emitting layer is a light-emitting layer configured to emit red color,

the second light-emitting layer is a light-emitting layer configured to emit green color,

the third light-emitting layer is a light-emitting layer configured to emit blue color,

the first high refractive index layer is formed of a high refractive index resin containing a first absorption agent that absorbs visible light in a wavelength range of 610 nm or less,

the second high refractive index layer is formed of a high refractive index resin containing a second absorption agent that absorbs visible light in a wavelength range of 530 nm or less and a third absorption agent that absorbs light in a wavelength range of 560 nm or more,

the third high refractive index layer is formed of a high refractive index resin containing a fourth absorption agent that absorbs visible light in a wavelength range of 480 nm or more, and

the spacer is formed by at least one of a layer made of a material identical to the material of the first high refractive index layer, a layer made of a material identical to the material of the second high refractive index layer, and a layer made of a material identical to the material of the third high refractive index layer.

### Thirtieth Aspect

The display device according to the twenty-seventh aspect, wherein

the first light-emitting layer is a light-emitting layer configured to emit red color,

the second light-emitting layer is a light-emitting layer configured to emit green color,

the third light-emitting layer is a light-emitting layer configured to emit blue color,

the first high refractive index layer and the third high refractive index layer are each formed of a high refractive index resin containing a fifth absorption agent that absorbs visible light in a wavelength range from 530 nm to 560 nm,

the second high refractive index layer is formed of a high refractive index resin containing a second absorption agent that absorbs visible light in a wavelength range of 530 nm or less and a third absorption agent that absorbs visible light in a wavelength range of 560 nm or more, and

the spacer is formed by at least one of a layer made of a material identical to the material of either the first high refractive index layer or the third high refractive index layer, and a layer made of a material identical to the material of the second high refractive index layer.

### Thirty-First Aspect

The display device according to the twenty-seventh aspect, wherein

the first light-emitting layer is a light-emitting layer configured to emit red color,

the second light-emitting layer is a light-emitting layer configured to emit green color,

the third light-emitting layer is a light-emitting layer configured to emit blue color,

the first high refractive index layer and the third high refractive index layer are each formed of a high refractive index resin containing a fifth absorption agent that absorbs visible light in a wavelength range from 530 nm to 560 nm,

the second high refractive index layer is formed of a high refractive index resin, and

the spacer is formed by at least one of a layer made of a material identical to the material of either the first high refractive index layer or the third high refractive index layer, and a layer made of a material identical to the material of the second high refractive index layer.

### Thirty-Second Aspect

The display device according to the twenty-seventh aspect, further including an edge cover layer covering an end portion of the first electrode, wherein

the first light-emitting layer is a light-emitting layer configured to emit red color,

the second light-emitting layer is a light-emitting layer configured to emit green color,

the third light-emitting layer is a light-emitting layer configured to emit blue color,

the first high refractive index layer is formed by a layered film of a first high refractive index resin layer made of a high refractive index resin containing a fifth absorption agent that absorbs visible light in a wavelength range from 530 nm to 560 nm, and a second high refractive index resin layer made of a high refractive index resin containing a sixth absorption agent that absorbs visible light in a wavelength range of 480 nm or less,

the second high refractive index layer is formed by a layered film of the second high refractive index resin layer made of the high refractive index resin containing the sixth absorption agent that absorbs visible light in the wavelength range of 480 nm or less, and a third high refractive index resin layer made of a high refractive index resin containing a seventh absorption agent that absorbs visible light in a wavelength range of 610 nm or more,

the third high refractive index layer is formed by a layered film of the first high refractive index resin layer made of the high refractive index resin containing the fifth absorption agent that absorbs visible light in the wavelength range from 530 nm to 560 nm, and the third high refractive index resin layer made of the high refractive index resin containing the seventh absorption agent that absorbs visible light in the wavelength range of 610 nm or more,

a spacer provided on the edge cover layer defining the first subpixel and the second subpixel is formed by a layer made of a material identical to the material of the second high refractive index resin layer,

a spacer provided on the edge cover layer defining the second subpixel and the third subpixel is formed by a layer made of a material identical to the material of the third high refractive index resin layer, and

a spacer provided on the edge cover layer defining the third subpixel and the first subpixel is formed by a layer made of a material identical to the material of the first high refractive index resin layer.

### Thirty-Third Aspect

The display device according to any one of the first to twenty-sixth aspects, wherein

a plurality of the subpixels are provided,

the plurality of subpixels include a first subpixel, a second subpixel, and a third subpixel,

each of the first subpixel, the second subpixel, and the third subpixel includes a fourth light-emitting element as the light-emitting element configured to emit white light,

a first high refractive index layer is provided as the high refractive index layer on the second electrode of the first subpixel

a second high refractive index layer is provided as the high refractive index layer on the second electrode of the second subpixel,

a third high refractive index layer is provided as the high refractive index layer on the second electrode of the third subpixel,

the first high refractive index layer is formed of a high refractive index resin containing a first absorption agent that absorbs visible light in a wavelength range of 610 nm or less,

the second high refractive index layer is formed of a high refractive index resin containing a second absorption agent that absorbs visible light in a wavelength range of 530 nm or less and a third absorption agent that absorbs light in a wavelength range of 560 nm or more,

the third high refractive index layer is formed of a high refractive index resin containing a fourth absorption agent that absorbs visible light in a wavelength range of 480 nm or more, and

the spacer is formed by at least one of a layer made of a material identical to the material of the first high refractive index layer, a layer made of a material identical to the material of the second high refractive index layer, and a layer made of a material identical to the material of the third high refractive index layer.

### Thirty-Fourth Aspect

A method for manufacturing a display device, the method including:

forming, on a first substrate, a first electrode that reflects visible light;

forming a function layer including a light-emitting layer after the forming a first electrode;

forming a second electrode that transmits visible light after the forming a function layer;

forming a reflective portion having a reflective surface inclined with respect to a surface on a side of the first substrate on which the first electrode is provided;

forming, after the forming a second electrode, a high refractive index layer, on the second electrode, that guides light entering from the second electrode side at an angle equal to or greater than a total reflection critical angle, to the reflective surface, and transmits light entering at an angle less than the total reflection critical angle; forming a second substrate that faces the surface on the side of the first substrate on which the first electrode is provided after the forming a high refractive index layer; and

forming, after the forming a high refractive index layer and before the forming a second substrate, a spacer that forms a gap layer having a certain thickness between the second substrate and the high refractive index layer provided at least in a region not overlapping the reflective portion in a plan view and having a refractive index lower than a refractive index of the high refractive index layer, and disposes the second substrate away from the reflective portion.

### Thirty-Fifth Aspect

The method for manufacturing the display device according to the thirty-fourth aspect, the method further including:

forming an edge cover layer covering an end portion of the first electrode between the forming a first electrode and the forming a function layer,

wherein the reflective portion is formed to cause at least part of the reflective portion to overlap the edge cover layer in a plan view in the forming a reflective portion.

### Thirty-Sixth Aspect

The method for manufacturing the display device according to the thirty-fifth aspect, wherein

in the forming an edge cover layer, a structural body that overlaps part of the function layer including the light-emitting layer in a plan view and is located below the reflective portion is formed together with the edge cover layer, and

in the forming a reflective portion, the reflective portion is formed in such a manner that at least part of the reflective portion overlaps the edge cover layer and the structural body in the plan view.

### Thirty-Seventh Aspect

The method for manufacturing the display device according to the thirty-fifth or thirty-sixth embodiment, wherein the spacer is formed on the edge cover layer in the forming a spacer.

### Thirty-Eighth Aspect

The method for manufacturing the display device according to any one of the thirty-fourth to thirty-seventh aspects, wherein

a material for forming the high refractive index layer in the forming a high refractive index layer and a material for forming the spacer in the forming a space are identical, and

the forming a high refractive index layer and the forming a spacer are identical.

### Thirty-Ninth Aspect

The method for manufacturing the display device according to any one of the thirty-fourth to thirty-seventh aspects, wherein

the forming a function layer includes

forming a first light-emitting layer to form the first light-emitting layer,

forming a second light-emitting layer to form the second light-emitting layer with a light emission peak wavelength shorter than a light emission peak wavelength emitted by the first light-emitting layer in a different region from the first light-emitting layer, and

forming a third light-emitting layer to form the third light-emitting layer with a light emission peak wavelength shorter than the light emission peak wavelength emitted by the second light-emitting layer in a region different from the first light-emitting layer and the second light-emitting layer,

the forming a high refractive index layer includes

forming a first high refractive index layer to form the first high refractive index layer into which light from the first light-emitting layer enters,

forming a second high refractive index layer to form the second high refractive index layer into which light from the second light-emitting layer enters, and

forming a third high refractive index layer to form the third high refractive index layer into which light from the third light-emitting layer enters,

the forming a spacer and the forming a high refractive index layer are identical, and

the spacer is formed by at least one of a layer made of a material identical to the material of the first high refractive index layer, a layer made of a material identical to the material of the second high refractive index layer, and a layer made of a material identical to the material of the third high refractive index layer.

### APPENDIX

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### INDUSTRIAL APPLICABILITY

The present invention can be utilized for a display device and a method for manufacturing the display device.

### REFERENCE SIGNS LIST

1, 1a, 1b, 1c Display device
2 Substrate including transistor (first substrate)
2S Surface on light-emitting element side of substrate including transistor
3 Barrier layer
4 Thin film transistor layer
5R Red light-emitting element (first light-emitting element)
5G Green light-emitting element (second light-emitting element)
5B Blue light-emitting element (third light-emitting element)
5W Light-emitting element configure to emit white light (fourth light-emitting element)
12 Substrate
16, 18, 20 Inorganic insulating film
21 Flattening film
22 First electrode
23E, 23′, 23″ Edge cover layer
23K Structural body
24R Function layer including red light-emitting layer
24G Function layer including green light-emitting layer
24B Function layer including blue light-emitting layer
24W Function layer including light-emitting layer
25 Second electrode
26, 26C Reflective portion
26H Reflective surface
27, 27a, 27′, 27″ High refractive index layer
27R First high refractive index layer
27G Second high refractive index layer
27B Third high refractive index layer
27M First high refractive index resin layer, First high refractive index layer, Third high
refractive index layer
27Y Second high refractive index resin layer
27C Third high refractive index resin layer
27R′ Layer made of same material as first high refractive index layer
27G′ Layer made of same material as second high refractive index layer
27B′ Layer made of same material as third high refractive index layer
27M′ Layer made of same material as first high refractive index resin layer
27Y′ Layer made of same material as second high refractive index resin layer
27C′ Layer made of same material as third high refractive index resin layer
28, 28a to 28g Spacer
28′, 28″, 28″ Spacer
29 Gap layer
30 Second substrate
PIX Pixel
RSP Red subpixel
GSP Green subpixel
BSP Blue subpixel
TR Transistor
SEM, SEM′, SEM″ Semiconductor film
G Gate electrode
D Drain electrode
S Source electrode
DA Display region
NDA Frame region

1. A display device, comprising:
a first substrate;
a subpixel including a light-emitting element in which a first electrode configured to reflect visible light, a function layer including a light-emitting layer, and a second electrode configured to transmit visible light are provided on the first substrate in that order from the first substrate side;
a reflective portion provided in part of the subpixel and having a reflective surface inclined with respect to a surface on the light-emitting element side of the first substrate;
a high refractive index layer that is provided on the second electrode, guides light entering from the second electrode side at an angle equal to or greater than a total reflection critical angle, to the reflective surface, and transmits light entering at an angle less than the total reflection critical angle;
a second substrate provided to face the surface on the light-emitting element side of the first substrate; and
a spacer configured to form a gap layer having a certain thickness between the second substrate and the high refractive index layer provided at least in a region not overlapping the reflective portion in a plan view, and dispose the second substrate away from the reflective portion,
wherein a refractive index of the high refractive index layer is higher than a refractive index of the gap layer.

2. The display device according to claim 1,
wherein the reflective portion is provided above the function layer including the light-emitting layer.

3. (canceled)

4. The display device according to claim 1,
wherein a difference between the refractive index of the high refractive index layer and the refractive index of the gap layer is larger than a difference between an average refractive index of the first electrode, the function layer including the light-emitting layer and the second electrode, and the refractive index of the high refractive index layer.

5. The display device according to claim 1,
wherein the average refractive index of the first electrode, the function layer including the light-emitting layer, and the second electrode is higher than the refractive index of the high refractive index layer.

6. (canceled)

7. The display device according to claim 1,
wherein the reflective portion includes a conductive material, and is formed on the second electrode to be in contact with the second electrode.

8. The display device according to claim 1,
wherein the reflective portion includes a conductive material, and is formed between the second electrode and the function layer including the light-emitting layer to be in contact with the second electrode and the function layer including the light-emitting layer.

9. The display device according to claim 1,
wherein the reflective portion includes a light scattering agent.

10-11. (canceled)

12. The display device according to claim 1, further comprising:
an edge cover layer covering an end portion of the first electrode,
wherein the spacer is formed in a dot shape on the edge cover layer.

13-16. (canceled)

17. The display device according to claim 1, further comprising:
a structural body that overlaps part of the function layer including the light-emitting layer in a plan view and is provided below the reflective portion; and
an edge cover layer covering an end portion of the first electrode,
wherein at least part of the reflective portion overlaps the edge cover layer and the structural body in the plan view,
wherein a maximum height of the edge cover layer is higher than a maximum height of the structural body by a thickness of the function layer including the light-emitting layer.

18-21. (canceled)

22. The display device according to claim 1,
wherein the gap layer is filled with a low refractive index medium having a refractive index lower than the refractive index of the high refractive index layer,
wherein the low refractive index medium includes at least one of a resin with a refractive index lower than the refractive index of the high refractive index layer, a hollow bead with a refractive index lower than the refractive index of the high refractive index layer, and air.

23-25. (canceled)

26. The display device according to claim 1,
wherein the second substrate further includes a circular polarizer.

27. The display device according to claim 1,
wherein a plurality of the subpixels are provided,
the plurality of subpixels include a first subpixel, a second subpixel, and a third subpixel,
the first subpixel is provided with, as the light-emitting element, a first light-emitting element including the first electrode, a function layer including a first light-emitting layer as the light-emitting layer, and the second electrode,
the second subpixel is provided with, as the light-emitting element, a second light-emitting element including the first electrode, a function layer including a second light-emitting layer as the light-emitting layer, and the second electrode,
the third subpixel is provided with, as the light-emitting element, a third light-emitting element including the first electrode, a function layer including a third light-emitting layer as the light-emitting layer, and the second electrode,
a light emission peak wavelength emitted by the first light-emitting layer is longer than a light emission peak wavelength emitted by the second light-emitting layer,
the light emission peak wavelength emitted by the second light-emitting layer is longer than a light emission peak wavelength emitted by the third light-emitting layer, a first high refractive index layer is provided as the high refractive index layer on the second electrode of the first subpixel,
a second high refractive index layer is provided as the high refractive index layer on the second electrode of the second subpixel, and
a third high refractive index layer is provided as the high refractive index layer on the second electrode of the third subpixel.

28. The display device according to claim 27,
wherein the first high refractive index layer, the second high refractive index layer, the third high refractive index layer, and the spacer are each formed of a high refractive index resin made of an identical material.

29. The display device according to claim 27,
wherein the first light-emitting layer is a light-emitting layer configured to emit red color,
the second light-emitting layer is a light-emitting layer configured to emit green color,
the third light-emitting layer is a light-emitting layer configured to emit blue color,
the first high refractive index layer is formed of a high refractive index resin containing a first absorption agent that absorbs visible light in a wavelength range of 610 nm or less,
the second high refractive index layer is formed of a high refractive index resin containing a second absorption agent that absorbs visible light in a wavelength range of 530 nm or less and a third absorption agent that absorbs visible light in a wavelength range of 560 nm or more,
the third high refractive index layer is formed of a high refractive index resin containing a fourth absorption agent that absorbs visible light in a wavelength range of 480 nm or more, and
the spacer is formed by at least one of a layer made of a material identical to the material of the first high refractive index layer, a layer made of a material identical to the material of the second high refractive index layer, and a layer made of a material identical to the material of the third high refractive index layer.

30. The display device according to claim 27,
wherein the first light-emitting layer is a light-emitting layer configured to emit red color,
the second light-emitting layer is a light-emitting layer configured to emit green color,
the third light-emitting layer is a light-emitting layer configured to emit blue color,
the first high refractive index layer and the third high refractive index layer are each formed of a high refractive index resin containing a fifth absorption agent that absorbs visible light in a wavelength range from 530 nm to 560 nm,
the second high refractive index layer is formed of a high refractive index resin containing a second absorption agent that absorbs visible light in a wavelength range of 530 nm or less and a third absorption agent that absorbs visible light in a wavelength range of 560 nm or more, and
the spacer is formed by at least one of a layer made of a material identical to the material of either the first high refractive index layer or the third high refractive index layer, and a layer made of a material identical to the material of the second high refractive index layer.

31. The display device according to claim 27,
wherein the first light-emitting layer is a light-emitting layer configured to emit red color,
the second light-emitting layer is a light-emitting layer configured to emit green color,
the third light-emitting layer is a light-emitting layer configured to emit blue color,
the first high refractive index layer and the third high refractive index layer are each formed of a high refractive index resin containing a fifth absorption agent that absorbs visible light in a wavelength range from 530 nm to 560 nm,
the second high refractive index layer is formed of a high refractive index resin, and
the spacer is formed by at least one of a layer made of a material identical to the material of either the first high refractive index layer or the third high refractive index layer, and a layer made of a material identical to the material of the second high refractive index layer.

32. The display device according to claim 27, further comprising:
an edge cover layer covering an end portion of the first electrode,
wherein the first light-emitting layer is a light-emitting layer configured to emit red color,
the second light-emitting layer is a light-emitting layer configured to emit green color,
the third light-emitting layer is a light-emitting layer configured to emit blue color,
the first high refractive index layer is formed by a layered film of a first high refractive index resin layer made of a high refractive index resin containing a fifth absorption agent that absorbs visible light in a wavelength range from 530 nm to 560 nm, and a second high refractive index resin layer made of a high refractive index resin containing a sixth absorption agent that absorbs visible light in a wavelength range of 480 nm or less,
the second high refractive index layer is formed by a layered film of the second high refractive index resin layer made of the high refractive index resin containing the sixth absorption agent that absorbs visible light in the wavelength range of 480 nm or less, and a third high refractive index resin layer made of a high refractive index resin containing a seventh absorption agent that absorbs visible light in a wavelength range of 610 nm or more,
the third high refractive index layer is formed by a layered film of the first high refractive index resin layer made of the high refractive index resin containing the fifth absorption agent that absorbs visible light in the wavelength range from 530 nm to 560 nm, and the third high refractive index resin layer made of the high refractive index resin containing the seventh absorption agent that absorbs visible light in the wavelength range of 610 nm or more,
a spacer provided on the edge cover layer defining the first subpixel and the second subpixel is formed by a layer made of a material identical to the material of the second high refractive index resin layer,
a spacer provided on the edge cover layer defining the second subpixel and the third subpixel is formed by a layer made of a material identical to the material of the third high refractive index resin layer, and
a spacer provided on the edge cover layer defining the third subpixel and the first subpixel is formed by a layer made of a material identical to the material of the first high refractive index resin layer.

33. The display device according to claim 1,
wherein a plurality of the subpixels are provided,
the plurality of subpixels include a first subpixel, a second subpixel, and a third subpixel,
each of the first subpixel, the second subpixel, and the third subpixel includes a fourth light-emitting element as the light-emitting element configured to emit white light,
a first high refractive index layer is provided as the high refractive index layer on the second electrode of the first subpixel
a second high refractive index layer is provided as the high refractive index layer on the second electrode of the second subpixel,
a third high refractive index layer is provided as the high refractive index layer on the second electrode of the third subpixel,
the first high refractive index layer is formed of a high refractive index resin containing a first absorption agent that absorbs visible light in a wavelength range of 610 nm or less,
the second high refractive index layer is formed of a high refractive index resin containing a second absorption agent that absorbs visible light in a wavelength range of 530 nm or less and a third absorption agent that absorbs visible light in a wavelength range of 560 nm or more,
the third high refractive index layer is formed of a high refractive index resin containing a fourth absorption agent that absorbs visible light in a wavelength range of 480 nm or more, and
the spacer is formed by at least one of a layer made of a material identical to the material of the first high refractive index layer, a layer made of a material identical to the material of the second high refractive index layer, and a layer made of a material identical to the material of the third high refractive index layer.

34. A method for manufacturing a display device, the method comprising:
forming, on a first substrate, a first electrode that reflects visible light;
forming a function layer including a light-emitting layer after the forming a first electrode;
forming a second electrode that transmits visible light after the forming a function layer;
forming a reflective portion having a reflective surface inclined with respect to a surface on a side of the first substrate on which the first electrode is provided;
forming, after the forming a second electrode, a high refractive index layer, on the second electrode, that guides light entering from the second electrode side at an angle equal to or greater than a total reflection critical angle, to the reflective surface, and transmits light entering at an angle less than the total reflection critical angle;
forming a second substrate that faces the surface on the side of the first substrate on which the first electrode is provided after the forming a high refractive index layer; and
forming, after the forming a high refractive index layer and before the forming a second substrate, a spacer that forms a gap layer having a certain thickness between the second substrate and the high refractive index layer provided at least in a region not overlapping the reflective portion in a plan view and having a refractive index lower than a refractive index of the high refractive index layer, and disposes the second substrate away from the reflective portion.

35. The method for manufacturing the display device according to claim 34, the method further comprising:
forming an edge cover layer covering an end portion of the first electrode between the forming a first electrode and the forming a function layer,
wherein the reflective portion is formed to cause at least part of the reflective portion to overlap the edge cover layer in a plan view in the forming a reflective portion.

36-39. (canceled)
